(19) United States
(12) Patent Application Publication
(10) Pub. No.: US 2026/0080947 A1
(43) Pub. Date: Mar. 19, 2026

(54) SEMICONDUCTOR DEVICE AND OPERATING METHOD THEREOF AND SYSTEM

(71) Applicant: Yangtze Momory Technologies Holding Co., Ltd., Wuhan (CN)

(72) Inventors: Wenhao Xiao, Wuhan (CN); Wendong Wang, Wuhan (CN); Jianquan Jia, Wuhan (CN); Jiameng Cui, Wuhan (CN); Lei Jin, Wuhan (CN); Zongliang Huo, Wuhan (CN)

(21) Appl. No.: 19/238,040

(22) Filed: Jun. 13, 2025

Related U.S. Application Data
(63) Continuation of application No. PCT/CN2025/082579, filed on Mar. 14, 2025.

(30) Foreign Application Priority Data
Sep. 14, 2024 (CN) 20241129403.3

(51) Int. Cl. G11C 16/26; G11C 5/06; G11C 16/04; G11C 16/24; H10B 41/10; H10B 41/27; H10B 41/35; H10B 41/41; H10B 43/10; H10B 43/27; H10B 43/35; H10B 43/40

(52) U.S. Cl. CPC G11C 16/26; G11C 5/063; G11C 16/0483; G11C 16/24; H10B 41/10; H10B 41/27; H10B 41/35; H10B 41/41; H10B 43/10; H10B 43/27; H10B 43/35; H10B 43/40

(57) ABSTRACT

According to one aspect of the present disclosure, a semiconductor device is provided. The semiconductor device may include a memory array comprising at least one memory block. The memory block may include a plurality of memory string columns disposed in a first direction. Each of the memory string columns may include a plurality of memory strings disposed in a second direction perpendicular to the first direction. Each of the memory strings may include a plurality of memory cells disposed along a third direction and connected in series. The semiconductor device may include a bit line layer including at least one bit line group. The bit line group may include a plurality of bit lines disposed in the first direction. Each of the bit lines may extend along the second direction and is coupled to all memory strings of one of the memory string columns within the memory block.

### CROSS-REFERENCE TO RELATED APPLICATIONS

This application is a continuation of International Application No. PCT/CN2025/082579, filed on Mar. 14, 2025, which claims the benefit of priority to Chinese Application No. 202411295403.3, filed on Sep. 14, 2024, both of which are hereby incorporated by reference in its entireties.

### FIELD OF TECHNOLOGY

The present disclosure relates to the field of semiconductor technologies, and in particular, to a semiconductor device and an operating method thereof, and a system.

### BACKGROUND

With the continuous growth of AIGC (Artificial Intelligence Generated Content) model parameters, the traditional von Neumann's architecture is facing the problems of “memory wall” and “power consumption wall”, and the bandwidth between CPU (Central Processing Unit) and memory has become a bottleneck restricting the performance of AI (Artificial Intelligence) chips. Inspired by the working mode characteristics of the human brain, the computing in memory architecture has been vigorously developed in recent years. By embedding computing functions in memory, it avoids the back and forth transfer of data, reduces the impact of the “memory wall” and the “power consumption wall”, and it is expected to build a computing system with high computing power, high bandwidth and high energy efficiency.

### SUMMARY

According to one aspect of the present disclosure, a semiconductor device is provided. The semiconductor device may include a memory array including at least one memory block. The memory block may include a plurality of memory string columns disposed in a first direction. Each of the memory string columns may include a plurality of memory strings disposed in a second direction perpendicular to the first direction. Each of the memory strings may include a plurality of memory cells disposed along a third direction and connected in series. The semiconductor device may include a bit line layer including at least one bit line group. The bit line group may include a plurality of bit lines disposed in the first direction. Each of the bit lines may extend along the second direction and is coupled to all memory strings of one of the memory string columns within the memory block.

In some implementations, the plurality of memory strings in the memory block may be arranged into a plurality of memory string rows in the second direction. In some implementations, the memory block may be divided into a plurality of tiles in the second direction. In some implementations, each of the tiles may include at least one of the memory string rows. In some implementations, the at least one of the memory string rows may include one of the memory strings in each of the plurality of memory string columns. In some implementations, the memory strings of each of tiles may be coupled to a same select line.

In some implementations, the memory strings in adjacent memory string columns may be staggered disposed.

In some implementations, the memory array may include at least one memory plane, and the memory plane may include a plurality of memory blocks disposed in the second direction. In some implementations, the bit lines of the bit line group may extend along the second direction to be coupled to all memory strings of one of the memory string columns within each of the memory blocks in the memory plane.

In some implementations, the memory array may include at least one memory plane, and the memory plane may include a plurality of memory blocks disposed in the second direction. In some implementations, the bit line layer may include a plurality of bit line groups disposed in parallel in the second direction, the bit lines of each of the bit line groups may extend along the second direction to be coupled to all memory strings of one memory string column within some of the memory blocks in the memory plane, and a number of the memory blocks coupled to each of the bit line groups may be equal.

In some implementations, a current input/output terminal of the bit line may be disposed at an end of the bit line. In some implementations, the current input/output terminal of the bit line may be disposed in the middle of the bit line.

In some implementations, the semiconductor device may include a peripheral circuit coupled to the bit line and the select line. In some implementations, when performing an operation by using the semiconductor device, a plurality of target memory strings in a target memory block in the memory array may be configured to store a plurality of weight values. In some implementations, the peripheral circuit may be configured to apply respective input voltages to a plurality of target select lines coupled to the plurality of target memory strings within the target memory block. In some implementations, the peripheral circuit may be configured to sense currents on the bit lines coupled to the target memory strings.

In some implementations, the semiconductor device may include a peripheral circuit coupled to the bit line and the select line. In some implementations, when the semiconductor device performs data access, the peripheral circuit may be configured to perform a read operation simultaneously on the plurality of memory blocks coupled to different bit line groups within the memory plane.

In some implementations, the memory block may include a plurality of memory blocks arranged into a plurality of memory block layers along the third direction, and each of the memory block layers may include at least one memory block. In some implementations, the bit line layer may include a plurality of bit line layers, and memory blocks of different memory block layers may include coupled to bit lines in different bit line layers.

In some implementations, the semiconductor device may include a peripheral circuit coupled to the bit line and the select line. In some implementations, the peripheral circuit may be configured to perform a read operation or an operation simultaneously on the plurality memory blocks that are located in the different memory block layers and overlap with each other along the third direction.

In some implementations, the semiconductor device may include a source line layer located between a first memory block layer and a second memory block layer. In some implementations, the source line layer may include at least one source line, memory strings in two of the memory blocks overlapping along the third direction in the first memory block layer and the second memory block layer are coupled to a same source line. In some implementations, a bit line layer coupled to a memory block of the first memory block layer may be located on a side of the first memory block layer facing away from the second memory block layer. In some implementations, a bit line layer coupled to a memory block of the second memory block layer may be located on a side of the second memory block layer facing away from the first memory block layer.

In some implementations, the semiconductor device may include a peripheral circuit. In some implementations, the peripheral circuit may include an analog-to-digital conversion circuit. In some implementations, the peripheral circuit may include a digital-to-analog conversion circuit. In some implementations, the peripheral circuit may include a voltage generator. In some implementations, the peripheral circuit may include a column decoder. In some implementations, the peripheral circuit may include a control logic. In some implementations, the analog-to-digital conversion circuit may be coupled to the column decoder and the control logic, and the digital-to-analog conversion circuit may be coupled to the voltage generator and the control logic.

According to another aspect of the present disclosure, a semiconductor device is provided. The semiconductor device may include a stack structure including gate layers and dielectric layers alternately stacked. The semiconductor device may include a plurality of channel structures located in the stack structure and penetrating through the stack structure. The semiconductor device may include at least one first isolation structure extending along a first direction, located in the stack structure and penetrating through the stack structure. The at least one first isolation structure may divide the stack structure into a plurality of memory blocks in parallel along a second direction. Each of the memory blocks may include a plurality of channel structure columns disposed in the first direction. Each of the channel structure columns may be a plurality of channel structures disposed in the second direction. The first direction and the second direction may be perpendicular to each other and both perpendicular to a stacking direction of the stack structure. The semiconductor device may include a bit line layer located on a side of the stack structure along the stacking direction. The bit line layer may include at least one bit line group. The bit line group may include a plurality of bit lines disposed in the first direction. Each of the bit lines may extend along the second direction and coupled to all the channel structures of one of the channel structure columns within the memory block.

In some implementations, a segment of the bit line may overlap with the channel structures in the stacking direction.

In some implementations, a size of a width of the bit line along the first direction may be greater than or equal to 20 nm and less than or equal to 100 nm.

In some implementations, the gate layer may include a plurality of gate layers. In some implementations, the plurality of gate layers may include a plurality of control gate layers and a select gate layer located on a side of the plurality of control gate layers. In some implementations, all the channel structures in the memory block may include arranged into a plurality of channel structure rows in the second direction. In some implementations, the semiconductor device further includes at least one second isolation structure extending along the first direction, located in the stack structure and penetrating through the select gate layer. In some implementations, the at least one second isolation structure may divide the memory block into a plurality of tiles, each of the tiles may include at least one of the channel structure rows, and the at least one of the channel structure rows may include one of the channel structures in each of the plurality of channel structure columns.

In some implementations, the semiconductor device may include a bit line plug located on a side of the bit line facing away from the stack structure. In some implementations, the bit line plug may be located at an end or a middle of the bit line and is in contact with the bit line.

In some implementations, the stack structure may include a plurality of stack structures stacked along the stacking direction. In some implementations, the plurality of channel structures and the first isolation structure may be disposed within each of the stack structures. In some implementations, the bit line layer may include a plurality of bit line layers. In some implementations, the channel structures in different ones of the stack structures may be coupled to bit lines in different ones of the bit line layers.

In some implementations, the semiconductor device may include a plurality of semiconductor structures stacked along the stacking direction and bonded to each other. In some implementations, the plurality of semiconductor structures may include a first semiconductor structure and a plurality of second semiconductor structures located on a side of the first semiconductor structure, each of the second semiconductor structures may include at least one of the stack structures, and the first semiconductor structure may include a peripheral circuit.

In some implementations, the semiconductor device may include a source line layer located between a first stack structure and a second stack structure. In some implementations, the source line layer may include at least one source line, channel structures in the first stack structure and the second stack structure both extend into the source line layer, and channel structures in two of the memory blocks that overlap along the stacking direction in the first stack structure and the second stack structure may be coupled to a same source line. In some implementations, a bit line layer coupled to the first stack structure may be located on a side of the first stack structure facing away from the second stack structure, and a bit line layer coupled to the second stack structure may be located on a side of the second stack structure facing away from the first stack structure.

According to a further aspect of the present disclosure, a system is provided. The system may include at least one semiconductor device. The at least one semiconductor device may include a memory array including at least one memory block. The memory block may include a plurality of memory string columns disposed in a first direction. Each of the memory string columns may include a plurality of memory strings disposed in a second direction perpendicular to the first direction. Each of the memory strings may include a plurality of memory cells disposed along a third direction and connected in series. The semiconductor device may include a bit line layer including at least one bit line group. The bit line group may include a plurality of bit lines disposed in the first direction. Each of the bit lines may extend along the second direction and may be coupled to all memory strings of one of the memory string columns within the memory block. The system may include a controller coupled to the at least one semiconductor device and configured to control the semiconductor device.

According to another aspect of the present disclosure, a system is provided. The system may include at least one semiconductor device. The at least one semiconductor device may include a stack structure including gate layers and dielectric layers alternately stacked. The at least one semiconductor device may include a plurality of channel structures located in the stack structure and penetrating through the stack structure. The at least one semiconductor device may include at least one first isolation structure extending along a first direction, located in the stack structure, and penetrating through the stack structure. The at least one first isolation structure may divide the stack structure into a plurality of memory blocks in parallel along a second direction. Each of the memory blocks may include a plurality of channel structure columns disposed in the first direction. Each of the channel structure columns may include a plurality of channel structures disposed in the second direction. The first direction and the second direction may be perpendicular to each other and both perpendicular to a stacking direction of the stack structure. The at least one semiconductor device may include a bit line layer located on a side of the stack structure along the stacking direction. The bit line layer may include at least one bit line group. The bit line group may include a plurality of bit lines disposed in the first direction. Each of the bit lines extends along the second direction and coupled to all the channel structures of one of the channel structure columns within the memory block. The system may include a controller coupled to the at least one semiconductor device and configured to control the semiconductor device.

According to still a further aspect of the present disclosure, a method of operating a semiconductor device is provided. The method may include, when performing an in-memory operation by using the semiconductor device, applying respective input voltages to a plurality of target select lines coupled to a plurality of target memory strings in a target memory block. The method may include, when performing an in-memory operation by using the semiconductor device, sensing currents on bit lines coupled to the target memory strings. The semiconductor device may include at least one memory block including a plurality of memory string columns disposed in a first direction and a plurality of memory string rows disposed in a second direction perpendicular to the first direction. The memory block may be divided into a plurality of tiles in the second direction. Each of the tiles may include at least one of the memory string rows. The at least one of the memory string rows may include one memory string in each of the plurality of memory string columns, and all memory strings of each of the tiles may be coupled to a same select line. The semiconductor device may include a bit line layer including at least one bit line group. The bit line group may include a plurality of bit lines. Each of the bit lines may be coupled to all memory strings in one memory string column within the memory block. The semiconductor device may include a peripheral circuit coupled to the select line and the bit line.

In some implementations, the semiconductor device may further include a memory array including at least one memory plane. In some implementations, the memory plane may include a plurality of memory blocks disposed in the second direction, and the bit line layer may include a plurality of bit line groups disposed in parallel in the second direction. In some implementations, the bit lines of each of the bit line groups may extend along the second direction to be coupled to all memory strings of one memory string column within some of the memory blocks in the memory plane, and a number of the memory strings coupled to each of the bit line groups may be equal. In some implementations, the plurality of bit line groups may include a first bit line group coupled to a first target memory block and a second bit line group coupled to a second target memory block. In some implementations, the applying respective input voltages to the plurality of target select lines coupled to the plurality of target memory strings in the target memory block may include applying a plurality of first input voltages to a plurality of first target select lines coupled to a plurality of first target memory strings in the first target memory block respectively. In some implementations, the plurality of first input voltages may be related to a plurality of first input values in a first input vector. In some implementations, the applying respective input voltages to the plurality of target select lines coupled to the plurality of target memory strings in the target memory block may include applying a plurality of second input voltages to a plurality of second target select lines coupled to a plurality of second target memory strings in the second target memory block respectively. In some implementations, the plurality of second input voltages are related to a plurality of second input values in a second input vector. In some implementations, the sensing the currents on the bit lines coupled to the target memory strings may include sensing a first current on a first bit line coupled to a first target memory string within the first bit line group. In some implementations, the sensing the currents on the bit lines coupled to the target memory strings may include sensing a second current on a second bit line coupled to a second target memory string within the second bit line group.

In some implementations, the plurality of memory blocks may be arranged into a plurality of memory block layers along a third direction. In some implementations, the third direction may be perpendicular to the first direction and the second direction. In some implementations, each of the memory block layers may include at least one memory block, the bit line layer may include a plurality of bit line layers, and memory blocks of different memory block layers may be coupled to bit lines of different bit line layers. In some implementations, the plurality of memory block layers may include a first memory block layer including a third target memory block coupled to a third bit line group. In some implementations, the plurality of memory block layers may include a second memory block layer including a fourth target memory block coupled to a fourth bit line group. In some implementations, the applying respective input voltages to the plurality of target select lines coupled to the plurality of target memory strings in the target memory block may include applying a plurality of third input voltages to a plurality of third target select lines coupled to a third target memory string within the third target memory block respectively. In some implementations, the plurality of third input voltages may be related to a plurality of third input values in a third input vector. In some implementations, the applying respective input voltages to the plurality of target select lines coupled to the plurality of target memory strings in the target memory block may include applying a plurality of fourth input voltages to a plurality of fourth target select lines coupled to a fourth target memory string within the fourth target memory block respectively. In some implementations, the plurality of fourth input voltages may be related to a plurality of fourth input values in a fourth input vector. In some implementations, the sensing the currents on the bit lines coupled to the target memory strings may include sensing a third current on a third bit line coupled to the third target memory string within the third bit line group. In some implementations, the sensing the currents on the bit lines coupled to the target memory strings may include sensing a fourth current on a fourth bit line coupled to a fourth target memory string within the fourth bit line group simultaneously.

In the technical solution provided by the present disclosure, the memory block includes a plurality of memory string columns sequentially disposed along a first direction, and each memory string column includes a plurality of memory strings disposed in a second direction. The bit line extends in the second direction and is coupled to all memory strings in one memory string column within the memory block, in other words, one memory string column within the memory block is only coupled to one bit line. Such that the number of the memory strings coupled to one bit line in the memory block is maximum, so that the number of the select lines coupled to these memory strings is maximum. In the operation scheme where the input value of the input vector is mapped to the input voltage, and the input voltage is applied to the memory block through the select line, the bit line can be set in such a way so that the number of input values input in parallel in the input vector increases, the operation capability of the semiconductor device is improved, and the computing power requirement after the current big data and the artificial intelligence rise are better met. In addition, since each memory string is only coupled to one bit line, a larger distance can be provided between adjacent bit lines, so that the coupling capacitance between the bit lines is reduced, and the reading precision during data access and the calculation accuracy during the in-memory operation are improved. Furthermore, in the case of ensuring that the coupling capacitance meets the requirement, the width of the bit line can also be increased to reduce the resistance of the bit line, thereby reducing the bit line voltage drop in the operation phase and further improving the calculation accuracy.

### BRIEF DESCRIPTION OF THE DRAWINGS

FIG. 1 is a schematic diagram of a three-dimensional NAND type memory according to an example of the present disclosure.

FIG. 2 is a first schematic diagram of a semiconductor device including a peripheral circuit and a memory array according to an example of the present disclosure.

FIG. 3 is a second schematic diagram of a semiconductor device including a peripheral circuit and a memory array according to an example of the present disclosure.

FIG. 4 is a first schematic diagram of inputting an input voltage into a memory block by a top select line according to an example of the present disclosure.

FIG. 5 is a first schematic diagram of a semiconductor device including a memory array according to an example of the present disclosure.

FIG. 6 is a second schematic diagram of a semiconductor device including a memory array according to an example of the present disclosure.

FIG. 7 is a schematic diagram of a semiconductor device including a memory plane according to an example of the present disclosure.

FIG. 8 is a first schematic diagram of a memory plane including a memory block according to an example of the present disclosure.

FIG. 9 is a second schematic diagram of a memory plane including a memory block according to an example of the present disclosure.

FIG. 10 is a third schematic diagram of a memory plane including a memory block according to an example of the present disclosure.

FIG. 11 is a second schematic diagram of inputting an input voltage into a memory block by a top select line according to an example of the present disclosure.

FIG. 12 is a schematic diagram of a memory array including a plurality of memory blocks according to an example of the present disclosure.

FIG. 13a is a first schematic structural diagram of a semiconductor device according to an example of the present disclosure.

FIG. 13b is a second schematic structural diagram of a semiconductor device according to an example of the present disclosure.

FIG. 14 is a third schematic structural diagram of a semiconductor device according to an example of the present disclosure.

FIG. 15 is a fourth schematic structural diagram of a semiconductor device according to an example of the present disclosure.

FIG. 16 is a schematic flowchart of an operating method of a semiconductor device according to an example of the present disclosure.

FIG. 17a is a first schematic composition diagram of a system according to an example of the present disclosure.

FIG. 17b is a second schematic composition diagram of a system according to an example of the present disclosure.

FIG. 18 is a schematic diagram of an exemplary memory card with a memory system according to an example of the present disclosure.

FIG. 19 is a schematic diagram of an exemplary solid state drive with a memory system according to an example of the present disclosure

### DETAILED DESCRIPTION

Example aspects disclosed in the present disclosure will be described in more detail below with reference to the accompanying drawings. Although example aspects of the present disclosure are shown in the accompanying drawings, it should be understood that the present disclosure may be implemented in various forms and should not be limited to the aspects set forth herein. Rather, these aspects are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that, the present disclosure may be practiced without one or more of these details. In other examples, in order to avoid confusion with the present disclosure, some technical features known in the art are not described; that is, not all features of the actual examples are described here, and well-known functions and structures are not described in detail.

In the drawings, like reference numerals refer to like elements throughout.

It should be understood that spatial relation terms such as “beneath,” “below,” “lower,” “under”, “above,” “upper,” etc., may be used herein for ease of description to describe the relationship between one element or feature and other elements or features shown in the figures. It should be appreciated that, in addition to the orientations shown in the figures, the spatial-relation terms intent to also include different orientations of the devices in use and operation. For example, if the devices in the figures are flipped, then described as “below” or “under” or “beneath” other elements or features will be oriented “on” other elements or features. Thus, the example terms “below” and “beneath” may include both upper and lower orientations. The devices may be additionally oriented (rotated 90 degrees or other orientations) and the spatial description terminology used herein is interpreted accordingly.

A term used herein is for the purpose of describing a particular example only and is not to be considered as limitation of the present disclosure. As used herein, “a”, “an” and “said/the” in the singular form are intended to include the plural forms as well, unless the context indicated clearly otherwise. It should also be understood that the terms at least one of “consists of” or “comprising”, when used in this description, identify the presence of at least one of stated features, integers, steps, operations, elements or components, but do not exclude the presence and addition of at least one of one or more other features, integers, steps, operations, elements, components or groups. As used herein, the term “at least one of” includes any and all combinations of the related listed items.

In a classic von Neumann's computing architecture, a memory is separate from a processor, and data is transferred between the memory and the processor through a data bus. When executing the command, the processor first reads the data from the memory, and then writes the updated data back into the memory, and the frequent data migration leads to huge power consumption and time overheads; in addition, because the memory bandwidth is limited, the processing speed of the processor is limited by the access speed of the memory, which greatly affects the calculation performance. With the rise of applications such as big data and artificial intelligence, the processing of massive data has made the bottleneck of von Neumann's computing architecture increasingly prominent. In order to solve the bottleneck of the classic von Neumann's computing architecture, the computing in memory chip architecture emerges, and the basic idea is to embed a calculation function in the memory and directly use the memory to perform logic calculation, thereby reducing the amount of data transmission and the transmission distance between the memory and the processor, reducing the power consumption while improving the calculation performance, so that a computing system with high computing power, high bandwidth and high energy efficiency is expected to be constructed.

The computing in memory chip includes, but is not limited to, Static Random Access Memory (SRAM), NAND flash memory, and Dynamic Random Access Memory (DRAM). NAND flash memory is a non-volatile memory and has a large capacity, thus becoming a widely studied object in the computing in memory chip. The contents of the NAND flash memory will be introduced below.

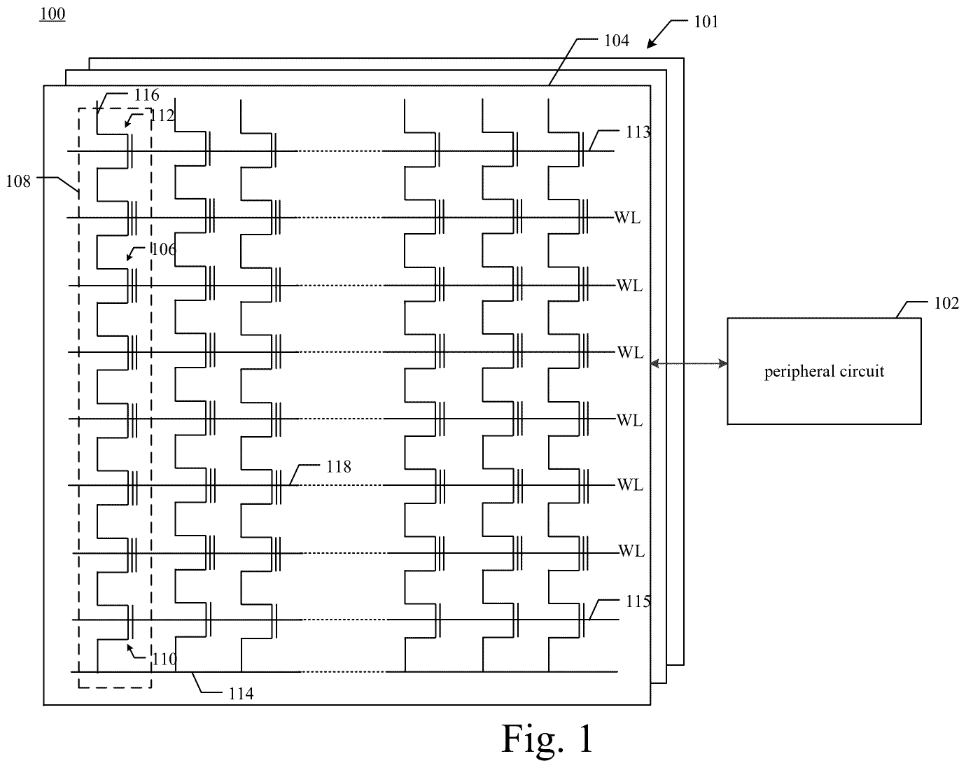

FIG. 1 is a schematic diagram of an exemplary semiconductor device including a peripheral circuit according to an example of the present disclosure. The semiconductor device 100 may include a memory array 101 and peripheral circuit 102 coupled to the memory array 101. Taking the memory array 101 being a three-dimensional NAND type memory array as an example for description, where the memory cell 106 is a NAND memory cell, the memory cell 106 is provided in the form of an array of memory strings (also referred to as memory cell strings) 108, and each memory string 108 extends vertically. In some implementations, each memory string 108 includes a plurality of memory cells 106 coupled in series and stacked vertically. Each memory cell 106 may maintain a continuous analog value, e.g., voltage or charge, depending on the number of electrons captured within the area of the memory cell 106. Each memory cell 106 may be a floating gate type memory cell including a floating gate transistor, or a charge trapping type memory cell including a charge trapping transistor.

In some implementations, each memory cell 106 is a single level cell (SLC) having two possible memory states and thus may store one bit of data. For example, the first memory state “0” may correspond to a first voltage range and the second memory state “1” may correspond to a second voltage range. In some implementations, each memory cell 106 is a multi-level cell capable of storing more than a single bit of data in four or more memory states, e.g., a multi-level cell (MLC) storing two bits per cell, a triple level cell (TLC) storing three bits per cell, or a quad-level cell (QLC) storing four bits per cell.

As shown in FIG. 1, each memory string 108 may include a bottom select gate (BSG) 110 at its source terminal and a top select gate (TSG) 112 at its drain terminal. The bottom select gate 110 and the top select gate 112 may be configured to activate the selected memory string 108 during read and program operations. In some implementations, the sources of the memory strings 108 in the same memory block 104 may be coupled through a common source line (CSL) 114.

In other words, all the memory strings 108 in the same memory block 104 have a common source (ACS). According to some implementations, the top select gate 112 of each memory string 108 is coupled to a respective bit line 116 from which data may be read or to which data may be written. A top select gate 112 of each memory string 108 is coupled to a respective top select line (TSL) 313, and a bottom select gate 110 of each memory string 108 is coupled to a respective bottom select line (BSL) 315. In some implementations, each memory string 308 is configured to be selected or deselected by applying a select voltage (e.g., a voltage higher than a threshold voltage of the top select gate 112) or a deselect voltage (e.g., 0 V) to the respective top select gate 112 through one or more top select lines 313, and/or by applying a select voltage (e.g., a voltage above a threshold voltage of the bottom select gate 110) or a deselect voltage (e.g., 0 V) to the respective bottom select gate 110 through one or more bottom select lines (BSL) 315. Memory cells 106 of adjacent memory strings 108 may be coupled by word lines 118 that select which row of memory cells 106 is affected by read and program operations.

With continued reference to FIG. 1, the peripheral circuit 102 may be coupled to the memory array 101 through bit lines 116, word lines 118, source lines 114, bottom select lines (BSL) 115, and top select lines (TSL) 113. The peripheral circuit 102 may include any suitable analog, digital, and mixed-signal circuit for facilitating operation of the memory array 101 by applying voltage signals and/or current signals to each of the memory cells 106 and sensing voltage signals and/or current signals from each of the memory cells 106 via bit lines 116, word lines 118, source lines 114, bottom select lines 115, and top select lines 113. Peripheral circuit 102 may include various types of peripheral circuit formed using metal-oxide-semiconductor technology.

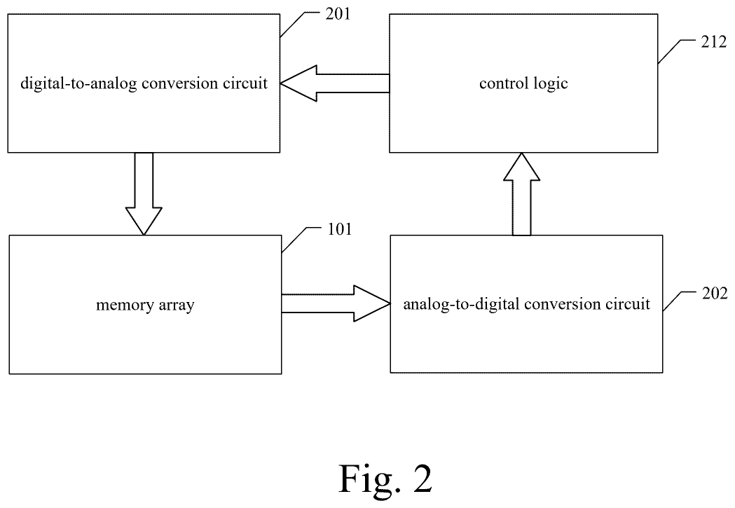

FIG. 2 is a first schematic diagram of a semiconductor device including a peripheral circuit and a memory array according to an example of the present disclosure. Referring to FIG. 1 and FIG. 2, the peripheral circuit 102 may include a control logic 212, a digital-to-analog conversion circuit 201 coupled to the control logic 212 and the memory array 101, and an analog-to-digital conversion circuit 202 coupled to the memory array 101 and the control logic 212. During an in-memory operation phase by using the semiconductor device, the digital-to-analog conversion circuit 201 may convert the digital signal into a voltage signal required by the memory array 101 in the computing in memory chip. The analog-to-digital conversion circuit 202 may convert the current signal output by the memory array 101 into a digital signal. The control logic 212 may be coupled to the peripheral circuit and configured to control operation of the peripheral circuit. The control logic 212 may be further configured to receive input data sent by the controller, and send the operation result to the controller.

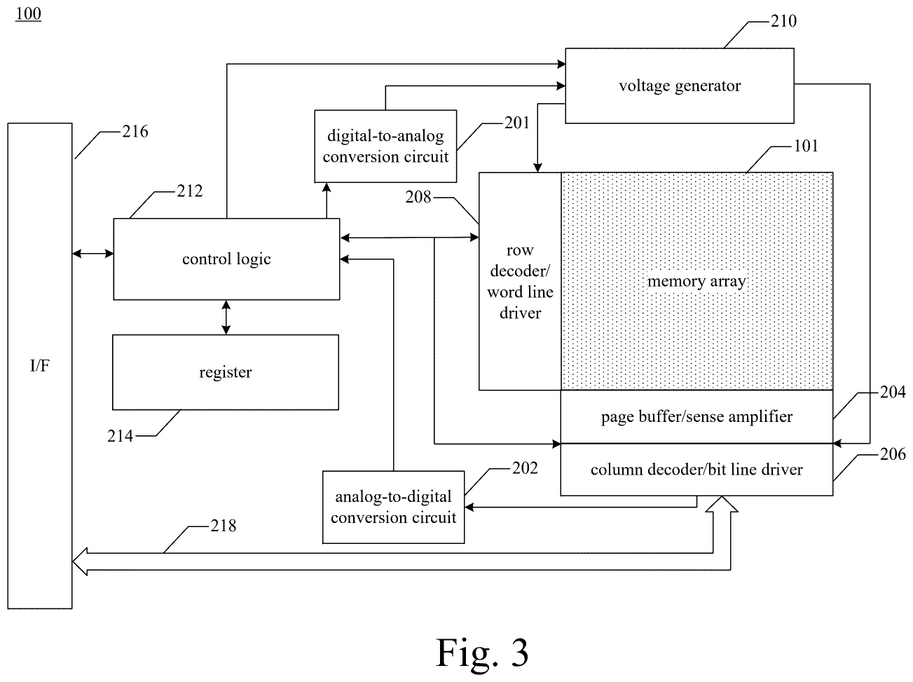

FIG. 3 is a second schematic diagram of a semiconductor device including a peripheral circuit and a memory array according to an example of the present disclosure. In addition to the circuit structure shown in FIG. 2, as shown in FIG. 3, the peripheral circuit 102 may further include a page buffer/sense amplifier 204, a column decoder/bit line (BL) driver 206, a row decoder/word line (WL) driver 208, a voltage generator 210, a register 214, an interface 216, and a data bus 218. It should be understood that, in some examples, additional peripheral circuits not shown in FIG. 2 and FIG. 3 may also be included.

The page buffer/sense amplifier 204 may be configured to read data from the memory array 101 and program (write) data to the memory array 101 according to control signals from the control logic 212. In an example, the page buffer/sense amplifier 204 may store a page of program data to be programmed into one page of the memory array 101. In another example, the page buffer/sense amplifier 204 may perform a program verify operation to ensure that the data has been properly programmed into the memory cell 106 coupled to the selected word line 118. In yet another example, the page buffer/sense amplifier 204 may also sense a low power signal from the bit line 116 representing a data bit stored in the memory cell 106, and amplify the small voltage swing to an identifiable logic level in a read operation. Column decoder/bit line driver 206 may be configured to be controlled by control logic 212 and select one or more memory strings 108 by applying a bit line voltage generated from voltage generator 210.

The row decoder/word line driver 208 may be configured to be controlled by the control logic 212, and select/deselect the memory block 104 of the memory array 101, and select/deselect the word line 118 of the memory block 104. The row decoder/word line driver 208 may also be configured to drive the word line 118 using the word line voltage generated from the voltage generator 210. In some implementations, row decoder/word line driver 208 may also select/deselect and drive BSL 115 and TSL 113. As described in detail below, the row decoder/word line driver 208 is configured to perform a program operation on the memory cells 306 coupled to the selected word line(s) 118. The voltage generator 210 may be configured to be controlled by the control logic 212 and generate word line voltages (e.g., read voltages, program voltages, pass voltages, select voltages, program verify voltages, etc., input voltages), bit line voltages, and source line voltages to be supplied to the memory array 301.

Registers 214 may be coupled to control logic 212 and include status registers, command registers, and address registers for storing status information, command operation codes (OP codes), and command addresses for controlling operation of each peripheral circuit. The interface 216 may be coupled to the control logic 212 and act as a control buffer to buffer control commands received from the host-side device and relay it to the control logic 212 and buffer status information received from the control logic 212 and relay it to the host-side device. Interface 216 may also be coupled to column decoder/bit line driver 206 via data bus 218, and act as a data I/O interface and a data buffer to buffer data and relay it to the memory array 101, or relay or buffer data from the memory array 101.

In some examples, as shown in FIG. 3, the digital-to-analog conversion circuit 201 may be connected to the control logic 212 and the voltage generator 210, and the analog-to-digital conversion circuit 202 may be connected to the control logic 212 and the column decoder/bit line driver 206. In the operation phase using the three-dimensional NAND type memory, the control logic receives input data sent by the controller, the digital-to-analog conversion circuit converts the input data to a voltage signal that needs to be applied on the word line or bit line, the voltage generator generates a corresponding voltage that needs to be applied on the word line or the bit line, the row decoder/word line driver is configured to drive the selected word line using the word line voltage generated from the voltage generator, or the column decoder/bit line driver is configured to drive the selected bit line using the bit line voltage generated from the voltage generator. The analog operation result obtained after the operation is transmitted to the analog-to-digital conversion circuit through the page buffer and the column decoder, the analog operation result is converted into a digital operation result through the analog-to-digital conversion circuit, and the final digital operation result is transmitted to the control logic.

In some examples, the computing in memory chip needs to implement a multiplication operation of the input data and the weight matrix, the input data may be an input matrix composed of a plurality of elements, the input matrix includes input vectors, the weight matrix is composed of a plurality of weights, and an accumulation operation with weights needs to be perform on a plurality of elements in the input data and a plurality of weights in the weight matrix, so as to obtain corresponding elements in the output data.

To implement the above operation functions, the memory array 101 in the semiconductor device 100 may be configured to store the weight matrix, where the weight in the weight matrix may be written into the memory array 101 according to a certain mapping rule, and each memory cell 106 in the memory array 101 may be configured to store a weight. In the operation phase, the semiconductor device 100 may receive input data from the controller, the input data may be an input matrix composed of a plurality of elements, and each element in the input data may be converted into an input voltage by the digital-to-analog conversion circuit 201, and the input voltage is input to the memory array 101 through the bit line 116, the word line 118, or the select line. The select line may be one of the top select line 113 and the bottom select line 115.

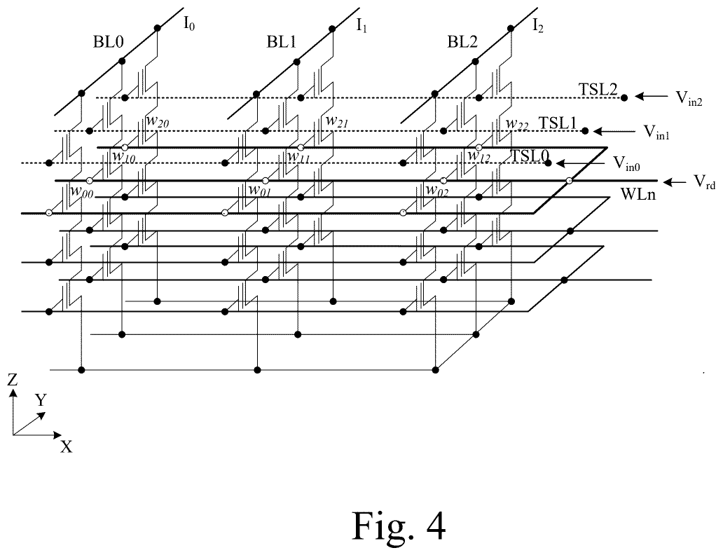

FIG. 4 is a schematic diagram of inputting an input voltage into a memory block by a top select line according to an example of the present disclosure. As shown in FIG. 4, the plurality of memory cells coupled to the target word line WLn may be configured to store a plurality of weights in the weight matrix, where the memory state corresponding to the threshold voltage of the memory cell may correspond to one weight.

The values of the plurality of elements in the input vector are mapped to a plurality of input voltages, which are applied to the memory block by the respective plurality of top select lines. Each element in the output matrix is mapped as the current I of the bit line, and the current on the bit line corresponds to the result of the sum of the products of the plurality of input voltages and their corresponding weights. Taking FIG. 4 as an example, when the respective input voltages Vᵢₙ₀, Vᵢₙ₁ and Vᵢₙ₂ are applied to the plurality of top select lines TSL0, TSL1, and TSL2, respectively, the current I₀ on the bit line BL0 corresponds to a result of Vᵢₙ₀×w₀₀+Vᵢₙ₁×w₁₀+Vᵢₙ₂×w₂₀, the current I₁ on the bit line BL1 corresponds to a result of Vᵢₙ₀×w₀₁+Vᵢₙ₁×w₁₁+Vᵢₙ₂×w₂₁, and the current I₂ on the bit line BL2 corresponds to a result of Vᵢₙ₀×w₀₂+Vᵢₙ₁×w₁₂+Vᵢₙ₂×w₂₂.

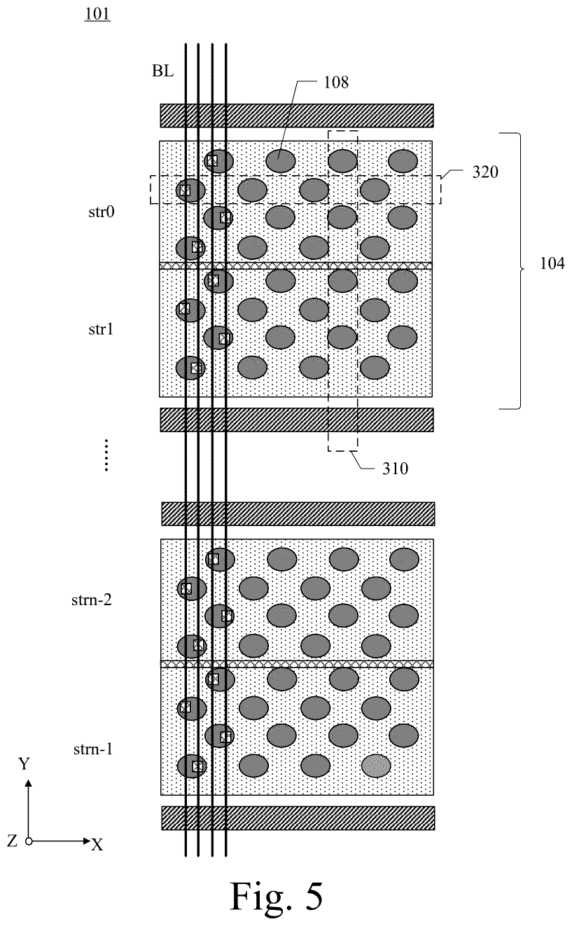

FIG. 5 is a first schematic diagram of a semiconductor device including a memory array according to an example of the present disclosure. As shown in FIG. 5, the memory array 101 includes a plurality of memory blocks 104, the memory block 104 includes a plurality of memory string columns 310 and a plurality of memory string rows 320, the plurality of memory string columns 310 are sequentially disposed in the X direction, and the plurality of memory string rows 320 are sequentially disposed in the Y direction. Adjacent memory strings 310 are disposed in a staggered manner, so that the plurality of memory strings 108 are disposed substantially in a hexagonal close-packed array; that is, six memory strings 108 adjacent to one memory string 108 form a hexagon. Each memory string 108 includes a plurality of memory cells disposed in parallel in the Z direction and connected in series, where a plurality of memory cells coupled to the same word line are configured to store a plurality of weight values in the weight matrix.

The bit lines BL extend along the Y direction, and each memory string column 310 is coupled to two bit lines BL. A memory string 108 with odd numbering in the memory string 310 is coupled to one bit line BL, and a memory string 108 with even numbering is coupled to the other bit line BL. The plurality of memory string rows 320 are divided into a plurality of tiles str0-str1 in the Y direction, and each tile includes four memory string rows 320. Each bit line BL is coupled to only one memory string 108 within each tile. All memory strings 108 within each tile are coupled to the same top select line.

When performing in-memory operations, one of the challenges faced by the semiconductor device shown in FIG. 5 is that the number of memory strings coupled to the bit lines is small, which means that the number of top select lines coupled to these memory strings is small, and the input voltage of each top select line corresponds to the value of one element in the input vector. The small number of memory strings coupled to the bit line leads to limited number of elements input in parallel during the in-memory operation, which in turn leads to limited computational power of the semiconductor device.

In this regard, the present disclosure provides the following implementations.

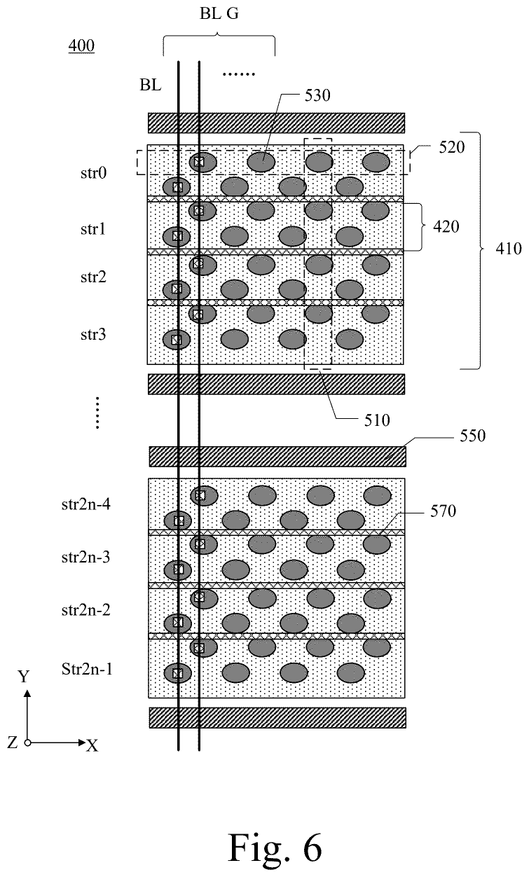

FIG. 6 is a second schematic diagram of a semiconductor device including a memory array according to an example of the present disclosure. As shown in FIG. 6, the semiconductor device includes a memory array 400 and a bit line layer, where the memory array 400 includes at least one memory block 410, the memory block 410 includes a plurality of memory string columns 510 disposed in a first direction, and a plurality of memory string rows 520 disposed in a second direction perpendicular to the first direction. Each memory string column 510 includes a plurality of memory strings 530 disposed in parallel and spaced apart along the second direction, and each memory string row 520 includes a plurality of memory strings 530 disposed in parallel and spaced apart along the first direction.

Each memory string 530 includes a top select gate, a plurality of memory cells, and a bottom select gate sequentially disposed along a third direction; and the top select gate, the plurality of memory cells, and the bottom select gate are connected in series. The memory string 530 may be a memory string 108 as shown in any of FIGS. 1 and 5 above.

The bit line layer includes at least one bit line group BL G, where the bit line group BL G includes a plurality of bit lines BL disposed in a first direction, and each bit line BL extends along the second direction and coupled to all memory strings 530 of one memory string column 510 within the memory block 410.

Before the semiconductor device shown in FIG. 6 is described in detail, various directions that may be used are defined. In the present disclosure, a stacking direction of the memory cells in the memory string is defined as a third direction, and a vertical first direction and a vertical second direction are defined in a plane perpendicular to the third direction. For example, the third direction is the Z direction, the first direction is the X direction, and the second direction is the Y direction.

As shown in FIG. 6, the bit line layer is located on a side of the memory block 410 along the third direction (Z direction), and the bit line in the bit line layer is coupled to the source/drain terminal of the select gate in the memory string. The select gate may be one of a top select gate and a bottom select gate. Herein, an example in which the bit line is coupled to the top select gate in the memory string is taken as an example for description.

In the present embodiment, the bit line BL extends along the second direction (Y direction) and is coupled to all the memory strings in one memory string column 510 in the memory block. In other words, one memory string column 510 in the memory block is coupled to only one bit line BL. Compared with the semiconductor device shown in FIG. 5, in the semiconductor device provided by the example, on the premise that the number and arrangement of the memory strings included in the memory block are unchanged, the number of memory strings coupled to the bit line is increased, so that the number of top select lines coupled to these memory strings is increased, and the number of elements input in parallel in the input vector corresponding to these top select lines is increased, and the operation capability of the semiconductor device is improved, so as to better meet the computing power requirement after the current big data and the artificial intelligence rise. In addition, two bit lines are disposed on a side of each memory string column along the third direction (Z direction) in FIG. 5, while in this example, only one bit line is disposed on a side of each memory string column along the third direction (Z direction), so that the distance between adjacent bit lines can be increased, so that the coupling capacitance between the bit lines is reduced, and the reading precision during data access and the operation accuracy during the in-memory operation are improved.

In some examples, the memory block is divided into a plurality of tiles (str) in a second direction (Y direction), where each tile includes at least one memory string row, and the at least one memory string row (e.g., all memory string column within the tile) includes one memory string in each of the plurality of memory string columns, and all of the memory strings within each tile are coupled to the same select line.

In this example, the rule for tile division is that the tile includes one memory string in each memory string column in all memory string columns in the memory block. All memory strings within the tile are coupled to the same top select line, such that a unique memory string can be determined by a bit line and a top select line.

The present disclosure does not limit the number of memory string rows included in a tile. The number of memory string rows included in the tile is related to the array form of the memory strings within the memory block. In some examples, the memory string columns 510 are periodically arranged within the memory block 410, where every i memory string columns is a column cycle, and i is a positive integer greater than 1. The i memory string columns in one column cycle are disposed in a staggered manner. Then, the memory string rows 520 are correspondingly disposed periodically, each row cycle includes i memory string rows, where the first memory string row includes one memory string in the first memory string column in each column cycle, the second memory string row includes one memory string in the second memory string column in each column cycle, and the i-th memory string row includes one memory string in the i-th memory string column in each column cycle. When the memory block is divided into tiles, each tile 420 includes i memory string rows 520.

FIG. 6 shows a case where i=2, that is, two adjacent memory string columns 510 are disposed in a staggered manner. The plurality of memory strings 510 include odd-numbered columns and even-numbered columns that are alternately disposed in the first direction (X direction), and the memory strings of the odd-numbered columns are offset by a certain distance in the second direction (Y direction) relative to the memory strings of the even-numbered columns to achieve the staggered arrangement. This arrangement allows all of the memory strings within the memory block to be arranged in a hexagonal close-packed array, e.g., six memory strings adjacent to one memory string form a hexagon. In the hexagonal close-packed array, a first one of the two adjacent memory string rows 520 includes one memory string 530 in each of the plurality of odd-numbered columns, and a second memory string 520 includes one memory string 530 in each of the plurality of even-numbered columns.

After the memory block 410 shown in FIG. 6 is divided into a plurality of tiles 420, each tile 420 includes two adjacent memory string rows 520. The two memory string rows within the tile can include one memory string in each of all of the memory string columns.

It should be understood that, in some other examples, the arrangement of the memory strings in the memory block 410 may also be that the memory strings in the two adjacent memory string columns 510 are aligned disposed along the first direction (X direction), so that all the memory strings within the memory block 410 are arranged in a rectangular array. Then, each memory string row 520 may include one memory string in each of all of the memory string columns 510. Based on this, each tile 420 includes only one memory string row 520.

With continued reference to FIG. 6, all of the memory strings within the tile 420 are coupled to the same select line, and the memory strings within the different tiles 420 are coupled to different select lines. Here, the select line is at least one of a top select line and a bottom select line. All of the memory strings within the tile are coupled to the same top select line; that is, the top select gates of all memory strings within the tile are coupled to the same top select line. All of the memory strings within the tile are coupled to the same bottom select line, that is, the bottom select gates of all memory strings within the tile are coupled to the same bottom select line.

It should be noted that, if the memory strings disposed in different tiles are coupled to different top select lines, the input voltages corresponding to the values of the elements in the input vector (also referred to as the input values) are applied to the memory block through the top select lines. If the memory strings disposed in different tiles are coupled to different bottom select lines, the input voltages corresponding to the input values are applied to the memory block through the bottom select lines. If the memory strings disposed in different tiles are coupled to different top select lines and coupled to different bottom select lines, the input voltages may be applied to the memory block through the top select lines, or the input voltages may be applied to the memory block through the bottom select lines.

Compared with the semiconductor device shown in FIG. 5, each tile (str) includes two memory strings 108 in each memory string column 310, while in this example, each tile 420 includes only one memory string 530 in each memory string column 510, such that on the premise that the number and arrangement of the memory strings in the memory block are unchanged, the number of tiles included in the memory block is increased; that is, the number of select lines coupled to the memory block is increased, the number of input values in the input vector (the number of input values may also be the number of input bits) input in parallel may be increased, thereby improving the computing power of the semiconductor device.

In some examples, as shown in FIG. 6, there are a plurality of memory blocks disposed in parallel along the second direction (Y direction), and each memory block includes a plurality of tiles disposed in parallel along the second direction (Y direction). For example, the number of tiles included in each memory block is equal. The number of tiles included in the memory block is not limited in the examples of the present disclosure. In practical applications, the number of tiles in one memory block may be 4, 6, 8, 16, 32, etc.

The bit lines of the bit line group may extend along a second direction to be coupled to all the memory strings in one memory string column within each of the plurality of memory blocks. In the semiconductor device shown in FIG. 5, a plurality of memory blocks includes a total of n tiles str0-strn-1, a bit line is coupled to one memory string in each tile, and the bit line is coupled to n memory strings of a plurality of memory blocks in total. In this example, after the number of the memory string row included in the tile in each memory block is reduced from 4 to 2, the number of tiles is doubled to 2n, and the bit line is coupled to the 2n memory strings in the plurality of memory blocks in total. In this way, the number of elements of the input vector input in parallel is doubled, and the operation capability is greatly improved. In an application scenario, for example, in a neural network, when the more the number of elements included in the input vector of the input layer is, the better the learning capability of the neural network is, and the higher the accuracy is.

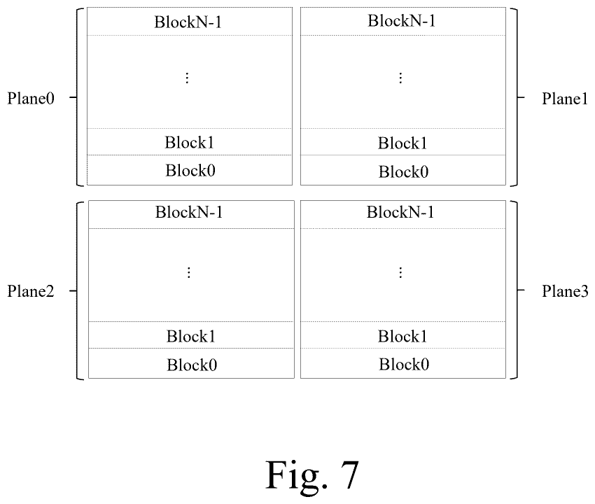

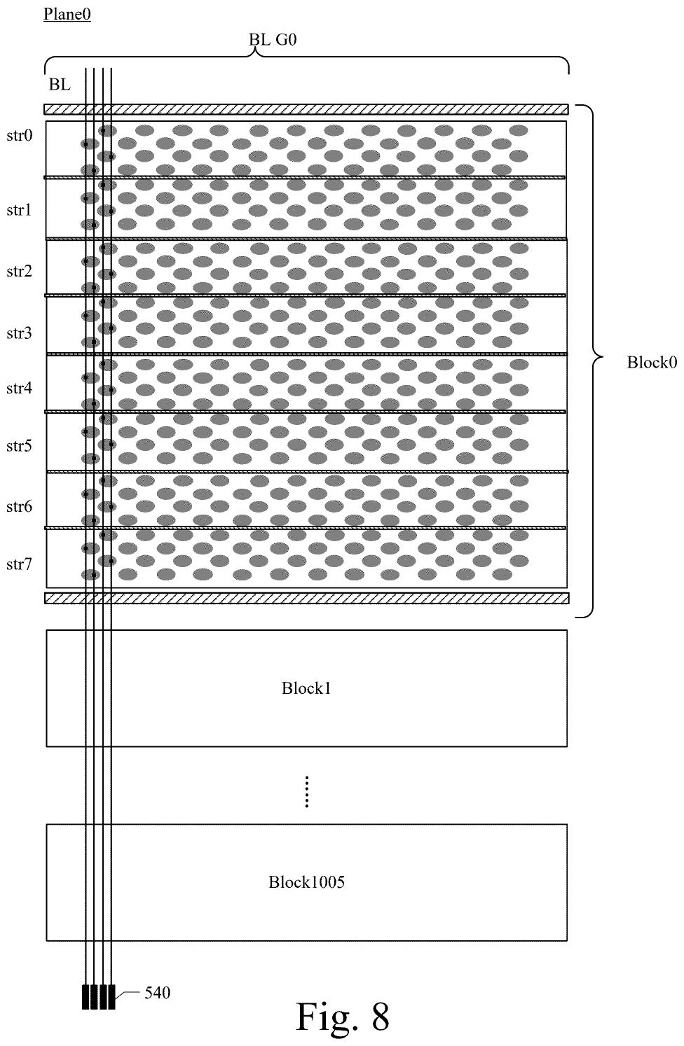

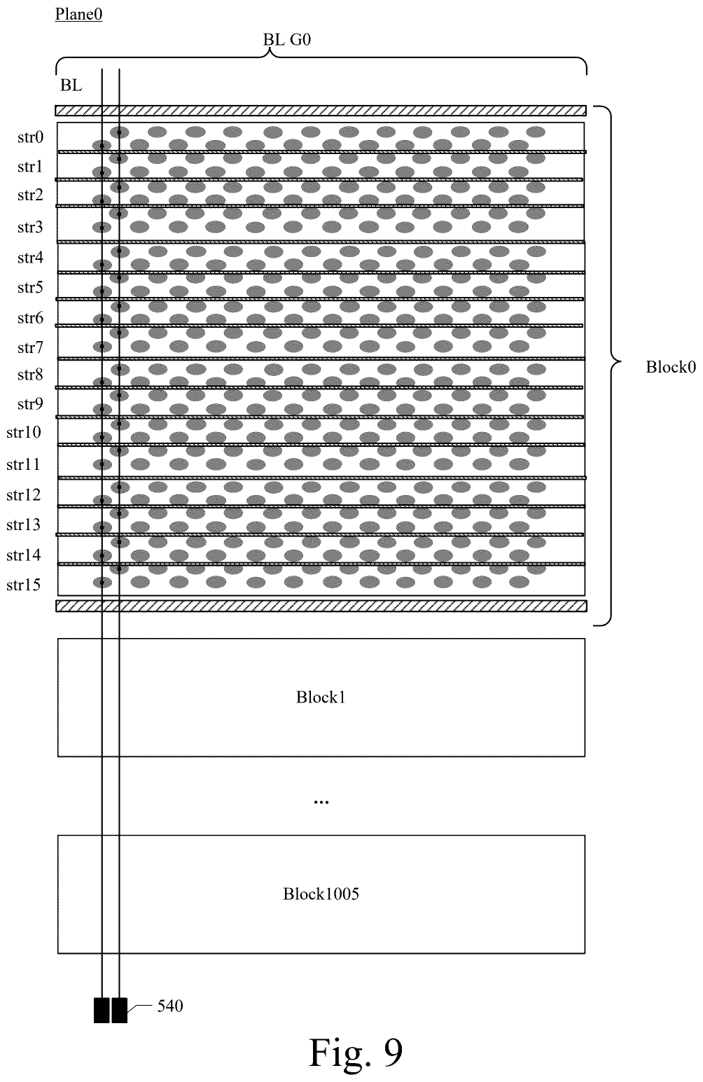

In some examples, the memory array may include at least one memory plane including a plurality of memory blocks disposed in a second direction (Y direction). FIG. 7 is a schematic diagram of a memory array including a plurality of memory planes according to an example of the present disclosure; FIG. 8 is a first schematic diagram of a memory plane including a plurality of memory blocks according to an example of the present disclosure; and FIG. 9 is a second schematic diagram 2 of a memory plane including a plurality of memory blocks according to an example of the present disclosure. As shown in FIG. 7, the memory array may include 4 memory planes, for example, a total of 4 memory planes, that is, Plane0, Plane1, Plane2, and Plane3, each memory plane includes a plurality of memory blocks, and two adjacent memory blocks are isolated from each other.

In FIG. 8, one memory plane may include 1006 memory blocks Block0-Block1005 disposed in parallel along the second direction, and in practical applications, the number of memory blocks in one memory plane is not limited thereto. Each memory block includes 8 tiles str0-str7, the structure of each tile is the same as in FIG. 5, that is, each tile includes 4 memory string rows. The bit line extends in the second direction and are coupled to the odd-numbered memory strings or even-numbered memory strings in the memory string columns, such that the bit line is coupled to one memory string within each die and the bit line is coupled to a total of 1006×8 memory strings.

In FIG. 9, the structure of each tile is the same as in FIG. 6, each tile includes two memory string rows, in this case, each memory block includes 16 memory tiles str0-str15, and the bit line extends along the second direction to be coupled to all memory strings of one memory string column within each memory block within the memory plane, so that the bit line is coupled to one memory string in each tile. The bit line is coupled to a total of 1006×8×2 memory strings.

Compared with the semiconductor device shown in FIG. 8, one memory plane includes N (for example, 1006) memory blocks, each memory block includes M (for example, 8) tiles; that is, one memory plane includes M×N (for example, 1006×8) tiles, and each bit line is coupled to M×N memory strings. In the example shown in FIG. 9, on the premise that the number and arrangement of the memory strings in the memory plane are unchanged, and each memory plane includes N (for example, 1006) memory blocks, one memory block includes 2M (for example, 2×8) tiles, one memory plane includes 2M×N (for example, 1006×8×2) tiles, and each bit line is coupled to 2M×N memory strings. The number of memory strings coupled to the bit line in one memory plane is doubled, which means that the maximum allowable number of input bits of the memory plane is doubled, thus improving the operation capability of the semiconductor device.

In some examples, the memory array includes at least one memory plane, and the memory plane includes a plurality of memory blocks disposed in the second direction. The bit line layer includes a plurality of bit line groups disposed in parallel in the second direction, and the bit lines of each bit line group extend in the second direction to be coupled to all the memory strings of one memory string column within some of the memory blocks in the memory plane.

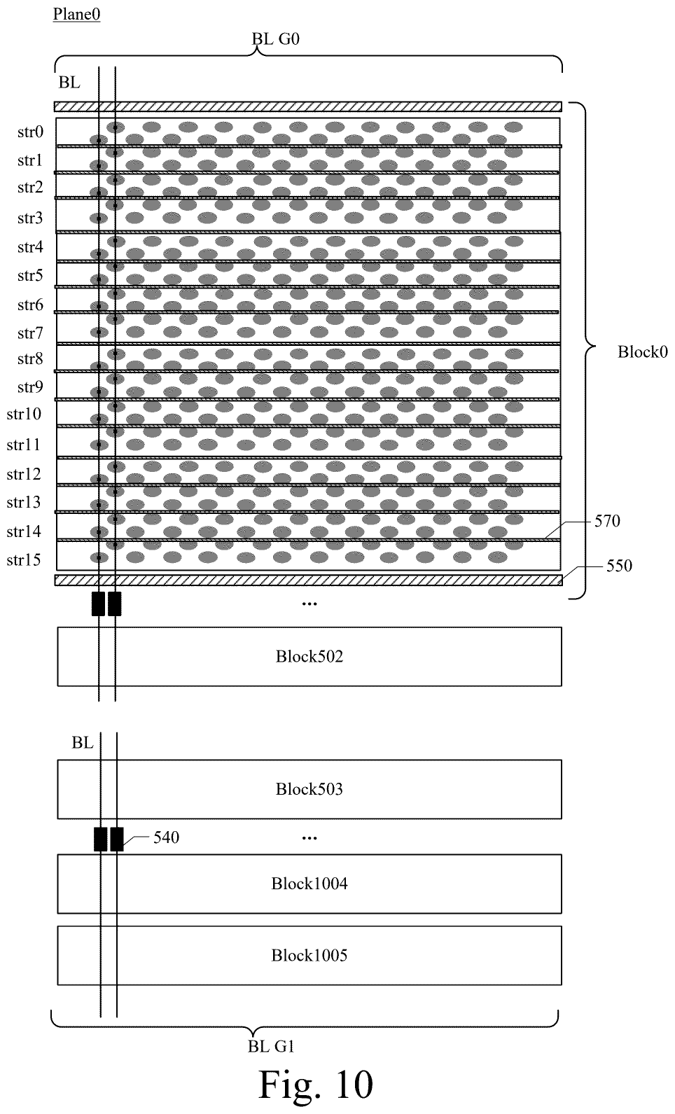

FIG. 10 is a third schematic diagram of a memory plane including a plurality of memory blocks according to an example of the present disclosure. As shown in FIG. 10, the memory plane includes a plurality of memory blocks Block0-Block1005 disposed in parallel in a second direction and isolated from each other. The bit line layer includes two bit line groups BL G0 and BL G1 disposed in the second direction, the bit line group BL G0 is coupled to half of the number of memory blocks Block0-Block502 in the memory plane, where the bit lines in the bit line group BL G0 extend along the second direction to be coupled to all the memory strings in one memory string column in one of the memory blocks Block0-Block502. The bit line group BL G1 is coupled to the other half of the number of memory blocks Block503 to Block1006 in the memory plane, where the bit lines in the bit line group BL G1 extend along the second direction to be coupled to all memory strings in one memory string column in each of the memory blocks Block0503-Block1006. It can be understood that the numbers of bit lines BL included in the bit line group BL G0 and the bit line group BL G1 are equal.

The bit line layer shown in FIG. 10, which comprises two bit line groups, is only an example and is not limited by this disclosure. In practical applications, the bit line layer can also comprise a number (such as 4, 6, 8, etc.) of bit line groups.

In some examples, as shown in FIG. 10, the numbers of memory blocks coupled to each bit line group are equal. In other words, the numbers of memory strings coupled to the bit line in each bit line group are equal. It can be understood that each bit line can be equally used without distinguishing when performing data memory or in-memory operation, which facilitates wear leveling.

Compared with the example shown in FIG. 8, one memory plane includes N memory blocks, each memory block includes M tiles, and each bit line is coupled to M×N memory strings. In this example, on the premise that the number and arrangement of the memory strings in the memory plane are unchanged, and each memory plane includes N memory blocks, one memory block includes 2 M tiles, and if the bit line layer includes two bit line groups, the number of memory strings coupled to each bit line is unchanged, but each bit line is only coupled to half of the memory blocks, then the length of the bit line is halved. In performing the in-memory operation, halving the length of the bit line can reduce the voltage drop (IR Drop) on the bit line and improve the accuracy of the calculation results.

In some examples, the current input/output terminals of the bit line are disposed at the ends of the bit line.

As shown in FIG. 9, the bit line has two end surfaces that are perpendicular to the extending direction (e.g., the second direction) of the bit line and are disposed opposite to each other, and the ends are one segment with a smaller distance from the end surfaces. The current input/output terminal 540 of the bit line is disposed at one of the ends.

For example, when the bit line layer includes a plurality of bit line groups, the current input/output terminals of the bit lines in different bit line groups may be disposed at the same end of the bit lines, or may not be disposed at the same end. Taking the bit line layer including the bit line groups BL G0 and BL G1 as an example, the current input/output terminals of the bit lines in the two bit line groups are not disposed at the same end, where the current input/output terminal 540 of the bit line in the bit line group BL G0 is disposed at an end of the bit line away from the bit line group BL G1, and the current input/output terminal 540 of the bit line in the bit line group BL G1 is disposed at an end of the bit line away from the bit line group BL G0. This arrangement facilitates disposing the connect structure at the two ends of the memory plane along the second direction, so as to couple the current input/output terminal 540 to the peripheral circuit.

For example, as shown in FIG. 9, the current input/output terminal 540 of the bit line is disposed on one side of all memory blocks coupled to the bit line.

In some examples, the current input/output terminal of the bit line is disposed in the middle of the bit line. For example, the middle of the bit line is middle ⅓ segment of the bit line along its extending direction. As shown in FIG. 10, the current input/output terminal 540 of the bit line is approximately in the middle of the bit line along its extending direction; that is, the distances from the current input/output terminal 540 of the bit line to the two end faces are approximately the same.

When an in-memory operation is performed, compared with the input/output terminal of the bit line being disposed on the end, in FIG. 10, the input/output terminal of the bit line is disposed in the middle of the bit line, so that the total current path from each memory string coupled to the bit line to the current input/output terminal is reduced, and the resistance value which affects the voltage drop on the bit line is reduced. In addition, in the two segments of bit line on two sides of the current input/output terminal, the current flowing through each segment of bit line is the current in only half of the memory strings, so the current flowing through the bit line is also reduced, so that the voltage drop on the bit line can be reduced, and the accuracy of the calculation result can be improved.

In some examples, the current input/output terminal 540 of the bit line does not overlap with the memory block in the third direction. As shown in FIG. 10, the semiconductor device further includes a first isolation structure 550 located between adjacent memory blocks. The current input/output terminal 540 is not located on a side of the memory block along the third direction, but is located on a side of the first isolation structure 550 between two adjacent memory blocks along the third direction. For example, the current input/output terminal 540 of the bit line is located above the first isolation structure 550.

In some examples, the peripheral circuit is connected to the current input/output terminal 540, and the peripheral circuit is coupled to the bit line through the input/output terminal.

In some examples, there are a plurality of memory blocks, the plurality of memory blocks are arranged into a plurality of memory block layers along the third direction, and each memory block layer includes at least one memory block. There are a plurality of bit line layers, and the memory blocks of different memory block layers are coupled to bit lines in different bit line layers.

The numbers of memory blocks included in each memory block layer are equal, and in the third direction, memory blocks in different memory block layers are aligned with each other. The number of bit line layers is equal to the number of memory block layers; that is, each memory block layer corresponds to one bit line layer, and the memory blocks in different memory block layers are coupled to bit lines in different bit line layers.

For example, the number of bit line groups included in each bit line layer is equal. In one implementation, each bit line layer may include only one bit line group coupled to all memory blocks within the memory block layer. In another implementation, each bit line layer includes a same number of a plurality of bit line groups, and a numbers of memory blocks coupled to each bit line group are equal. In this way, the memory blocks coupled to different bit line groups can be equally used, thus facilitating wear leveling, and prolonging the lifetime of the semiconductor device. Further, bit line groups located in different layers are aligned with each other along the third direction.

As another example, the numbers of bit line groups included in each bit line layer are not exactly the same. When the number of bit line layers is greater than or equal to three, it may be that the numbers of bit line groups included in some bit line layers are the same, but different from the numbers of bit line groups included in some other bit line layers. Alternatively, the numbers of bit line groups included in respective bit line layers are different from each other. When the number of the bit line layers is 2, the number of bit line groups included in each bit line layer being not exactly the same means that the number of bit line groups included in the two bit line layers are not the same. It can be understood that, when the number of bit line groups included in the bit line layer is different, the manner of coupling to the memory blocks of the memory block layer may be different. Taking an implementation for example, the first bit line layer includes one bit line group, the bit lines in the bit line group may be coupled to all the memory blocks of the first memory layer, the second bit line layer includes two bit line groups, and each bit line group may be coupled to half of the number of memory blocks in the second memory layer. In this way, the numbers of memory strings coupled to different bit line groups are different. Then, when performing the in-memory operation, an appropriate bit line group may be selected according to the number of elements in the input vector input in parallel, so as to avoid waste of computing power and reduce power consumption.

In some examples, the semiconductor device further includes a source line layer disposed on the other side of the memory block layer along the third direction and disposed opposite to the bit line layer. The source line layer includes at least one source line. The memory string is coupled to the source line, where a source terminal of the bottom select gate close to the source line layer in the memory string is coupled to the source line. For example, all memory strings within one memory block are coupled to the same common source line.

When the memory array includes a plurality of memory block layers, one of the arrangements of the plurality of memory block layers, the plurality of bit line layers and the source line layers is as follows: the source line layers, the memory block layers and the bit line layers are periodically disposed along the third direction, and each cycle includes a source line layer, a memory block layer and a bit line layer which are sequentially stacked along the third direction.

In some examples, the memory array includes adjacent first memory block layer and second memory block layer, the source line layer is located between the first memory block layer and the second memory block layer, the source line layer includes at least one source line, and the memory strings in the two memory blocks in the first memory block layer and the second memory block layer that overlap along the third direction are coupled to the same source line. The first bit line layer coupled to the memory block of the first memory block layer is located on a side of the first memory block layer facing away from the second memory block layer, and the second bit line layer coupled to the memory block of the second memory block layer is located on a side of the second memory block layer facing away from the first memory block layer.

In this example, since the memory strings of the two memory blocks that overlap along the third direction are coupled to the same source line, the two memory blocks may be programmed simultaneously. Referring back to FIG. 5 and FIG. 6, since the number of bit lines coupled to one memory string column is reduced from two to one, so that the number of bit lines coupled to the memory block in the first direction is halved, so when the read operation of data access is performed, the data output by the memory block at a time is also halved. In some examples, the read operation may be performed simultaneously on the two memory blocks that share the common source line in the two memory block layers, so that the data output by the memory plane at a time is unchanged.

In some examples, the first bit line layer, the first memory block layer, the source line layer, the second memory block layer, and the second bit line layer are periodically disposed along the third direction, and each cycle includes a first bit line layer, a first memory block layer, a source line layer, a second memory block layer, and a second bit line layer that are sequentially stacked along the third direction.

The semiconductor device according to any of the above examples of the present disclosure supports data storage and in-memory operations. The semiconductor device further includes a peripheral circuit coupled to the bit line, the word line, and the select line. In an operation phase performed using a semiconductor device, a plurality of target memory strings in a target memory block in a memory array are configured to store a plurality of weight values; and the peripheral circuit is configured to: apply a corresponding input voltage to a plurality of target select lines coupled to a plurality of target memory strings in the target memory block, apply read voltages to target word lines coupled to the target memory block, apply turn-on voltages to non-target word lines coupled to the target memory block, and sense currents on bit lines coupled to the target memory strings.

The in-memory operation includes a program phase and an operation phase. The program phase of the in-memory operation is to write the weight value into the memory cell, and in the program phase of the in-memory operation, the voltage on the target word line coupled to the memory cell to be written with the weight value is determined according to the weight value, and when the target word line is applied with different voltages, the memory cell obtains different memory states to correspondingly store different weight values. The operation phase of the in-memory operation is to perform an operation on the plurality of input values and the plurality of weight values, and in the inference phase of the in-memory operation, the input voltage applied to the target select line is determined based on the input value, and the result may be an analog quantity of the current on the bit line.

The target memory block is a memory block participating in in-memory operations in the memory array. The target memory string is a memory string to which the memory cell participating in the in-memory operation belongs. A memory cell participating in the in-memory operation is written with a weight value in a program phase, and becomes a memory cell storing a weight value in the inference phase. The target select line is a select line coupled to the target memory string. The target word line is a word line coupled to a memory cell participating in the in-memory operation.

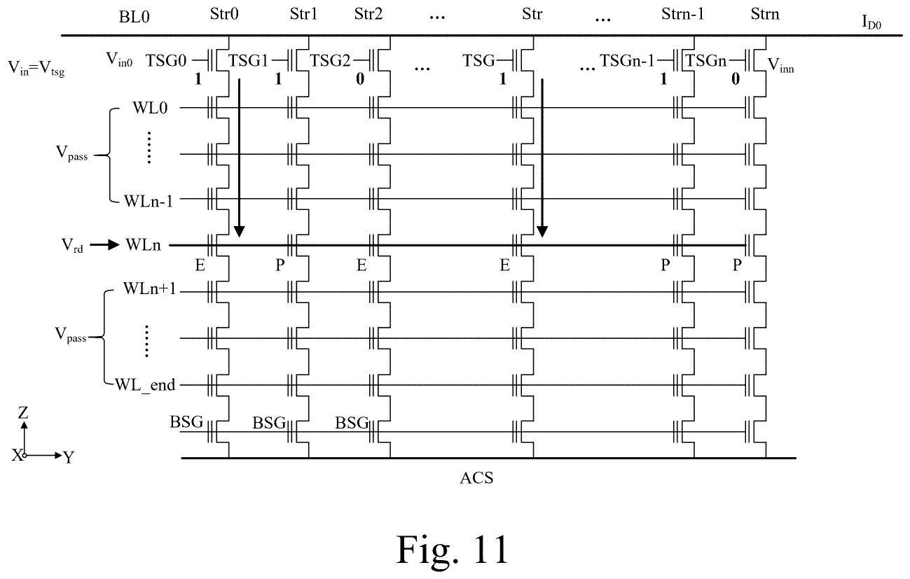

FIG. 11 is still another schematic diagram of inputting an input voltage into a memory block by a top select line according to an example of the present disclosure. A process of performing an in-memory operation by a semiconductor device according to an example of the present disclosure will be described below in detail with reference to FIG. 11.

As shown in FIG. 11, during the program phase of the in-memory operation, the plurality of memory cells coupled to the target word line WLn may be configured to store a plurality of weight values, and in an example, the memory state corresponding to the threshold voltage of the memory cell may correspond to one weight. In an example, the value of any weight in the weight matrix is “1” or “0”. Correspondingly, the memory cells in the memory block storing the weight matrix have a first memory state and a second memory state, which respectively correspond to the weight values “1” and “0”. For example, the first memory state may be an erased state E, and the second memory state may be a programmed state P. The erased state E and the programmed state P correspond to the weight values “1” and “0” respectively. In this example, taking the erased state E corresponding to the weight value “1” and the programmed state P corresponding to the weight value “0” as an example to illustrates a process of performing the in-memory operation by the memory array.

The input value in the input vector is mapped to the input voltage Vᵢₙ, which is applied to the memory block by the top select line. In an example, an input value in the input vector is “1” or “0”, which may be mapped to a high level input voltage and a low level input voltage. The high level input voltage is greater than the threshold voltage of the top select gate TSG, such that the top select gate TSG is turned on, and the low level input voltage is less than the threshold voltage of the top select gate TSG, such that the top select gate TSG is turned off. In this example, taking the high level input voltage corresponding to the input value “1” and the low level input voltage corresponding to the input value “0” as an example to illustrates a process of performing operation by the memory array.

In the operation phase, a read voltage V_{rd} is applied to the target word line WLn, a pass voltage Vₚₐₛₛ is applied to the non-target word lines WL0˜WLn−1 and WLn+1˜WL_end, the corresponding input voltages Vᵢₙ₀−Vᵢₙₙ are applied to a plurality of top select lines (that is, the gates of the plurality of top select gates TSG0-TSGn) respectively, and the current on the bit line BL0 is sensed.

The read voltage V_{rd} is greater than the threshold voltage of the memory cell in the erased state E, and is less than the threshold voltage of the memory cell in the programmed state P. In other words, the read voltage V_{rd} is between the threshold voltage distribution interval corresponding to an erased state E and the threshold voltage distribution interval corresponding to a programmed state P, and it can distinguish whether the memory cell has the erased state E or the programmed state P. Applying a pass voltage Vₚₐₛₛ to the non-target word lines coupled to the same memory block may cause the memory cells coupled to the non-target word lines to be turned on, in this context, the magnitude of the current in each memory string is only related to the threshold voltage (e.g., the memory state) of the memory cell coupled to the target word line WLn.

As shown in FIG. 11, when a high level input voltage is applied to the top select line, such that the top select gate is turned on, if the memory cell has the erased state E, the threshold voltage of the memory cell is less than the read voltage V_{rd}, so that the memory string to which the memory cell belongs is turned on and a significant current is generated; if the memory cell has the programmed state P, the threshold voltage of the memory cell is greater than the read voltage V_{rd}, so that the memory string to which the memory cell belongs is turned off, and no significant current is generated. Corresponding to an input value and a weight value, it can be understood as: when the input value is 1, if the weight value stored in the memory cell is 1, the memory string will generate a current; and when the input value is 1, if the weight value stored in the memory cell is 0, the memory string will not generate current.

Similarly, when a low level input voltage is applied to the top select line, the top select gate is turned off, and in this case, regardless of whether the memory cell has the erased state E or the programmed state P, no current is generated in the memory string. Corresponding to the input value and the weight value, it can be understood as: when the input value is 0, no matter the weight value is 1 or 0, no current is generated in the memory string. Based on this, it can be defined that the memory string generating current corresponds to the output value being 1, and the memory string not generating current corresponds to the output value being 0. Then, it can be understood that, when the input value is 1 and the weight value is 1, the output value is 1; when the input value is 1 and the weight value is 0, the output value is 0; when the input value is 0 and the weight value is 1, the output value is 0; when the input value is 0 and the weight value is 0, the output value is 0. This is consistent with the multiplication operation rule. Therefore, the input voltage can be applied to the memory block through the top select line, the weight value is stored through the memory cell, and the output value is obtained through the current of the bit line, thereby realizing the multiplication operation of the input vector and the weight matrix by using the memory array.

With continued reference to FIG. 11, when the respective input voltages Vᵢₙ₀, Vᵢₙ₁, . . . , Vᵢₙₙ are applied to a plurality of top select lines (that is, the gates of the plurality of top select gates TSG0, TSG1, . . . , to TSGn) respectively, the current obtained on the bit line BL0 is the sum of the currents of the plurality of memory strings, which corresponds to a result of the sum of the product of the plurality of input values Vᵢₙ₀, Vᵢₙ₁, . . . , Vᵢₙₙ and the corresponding weights w₀₀, w₁₀, w₂₀ . . . wₙ₁. That is, the value corresponding to the current on the bit line is I_{D0}=V_{¿0}×w₀₀+V_{¿1}×w₁₀+ . . . +Vᵢₙₙ×wₙ₀, and in this example, the current on the bit line is I_{D0}=1×1+1×0+0×1 . . . +1×0+0×0.

In some examples, when the input voltage is applied to the memory block through the top select line, in the operation phase, the peripheral circuit applies a first select voltage to the bottom select line, where the first select voltage is greater than the threshold voltage of the bottom select gate such that the bottom select gate is turned on. Conversely, when the input voltage is applied to the memory block through the bottom select line, a voltage greater than the threshold voltage of the top select gate is applied to the top select line.

In some examples, in the operation phase of the in-memory operation, the peripheral circuit is configured to: charge a sense node in a page buffer coupled to the bit line to a first preset voltage, and apply a second preset voltage less than the first preset voltage to the source line. In the operation phase, when the at least one memory string coupled to the bit line is turned on, since the first preset voltage of the sense node is greater than the second preset voltage of the source line, the current flowing from the bit line to the source line is generated in the memory string being turned on. The voltages of the sense nodes of different bit lines are all the first preset voltage, and when the numbers of the memory strings being turned on in the memory strings coupled to different bit lines are different, currents of different magnitudes may be generated in the bit lines to correspond to different operation results.

The page buffer herein may be the page buffer/sense amplifier 204 shown in FIG. 3.

In some examples, the semiconductor device performs a program step and a program verify step during a program phase of the in-memory operation. First, a program step is performed, the row selector applies a program voltage to the target word line to change the memory state of the memory cell coupled to the target word line, and applies a turn-on voltage to the non-target word line in the target memory block, and applies a third select voltage to the target select line to turn on the select gate coupled to the target select line, so as to select the target memory string. A deselect voltage is applied to the non-target select line to turn off the select gate coupled to the non-target select line, so as to inhibit writing weight values to the memory cells in the memory string coupled to the non-target select line.

Next, a program verify step is performed. A page buffer in the peripheral circuit charges the sense node and the bit line to a precharge voltage, and the row decoder applies a program verify voltage to the target word line. Under the effect of the program verify voltage, the memory cell coupled to the target word line may be turned on, so that the charge accumulated at the sense node may be discharged through the bit line and the channel, resulting in a voltage drop at the sense node. The memory states of the memory cells are different; that is, the threshold voltages are different, so that the sense node generates a different degree of voltage drop, and the page buffer determines whether the weight value stored therein is written into the memory cell according to the voltage of the sense node after discharged, that is, completes verification of the memory cell. The program verify result may be stored in a latch of the page buffer, and it may be determined whether the memory cell needs to continue to be programmed according to the program verify result. After the program verify result indicates that the memory cell is written with the weight value, the programming of the memory cell is terminated.

In this example, the input vector is mapped as the input voltage and applied to the memory array through the select line, the memory array stores the weight matrix, and the current on the bit line maps to the output value in the output matrix. In this way, the multipliers of the multiplication operations performed by the memory strings coupled to different select lines may be different, so that the operation flexibility can be improved, and more complex operations can be achieved through the semiconductor device. In addition, the input voltages corresponding to the plurality of elements in the input vector can be input simultaneously without being input sequentially, so that the operation efficiency can be improved on the basis of improving the operation flexibility.

In some examples, the peripheral circuit is configured to: perform multiplication operations of the same input vector and the weight matrix by using a plurality of memory blocks coupled to the same bit line group simultaneously. That is, the input voltages applied to the target select lines coupled to these memory blocks are related to the input values in the same input vector.

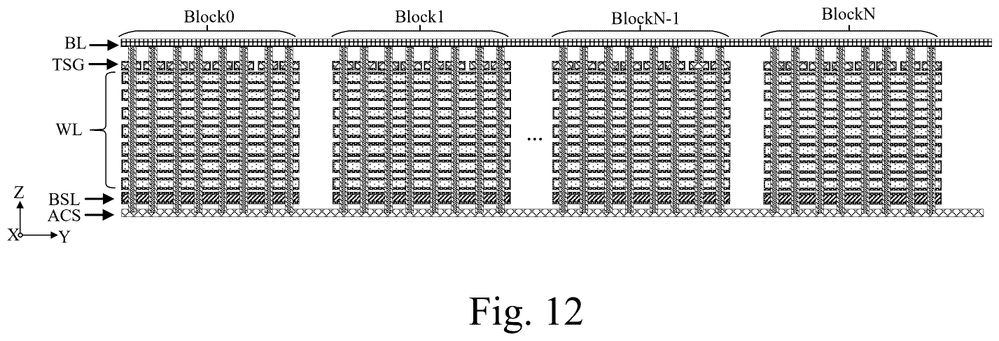

In an example, the peripheral circuit is configured to: apply read voltages to target word lines respectively coupled to a plurality of memory blocks coupled to the same bit line group; apply corresponding input voltages to a plurality of target select lines respectively coupled to the plurality of memory blocks coupled to the same bit line group; and sense a current on a bit line coupled to the plurality of memory blocks. FIG. 12 is a schematic diagram of a memory array including a plurality of memory blocks according to an example of the present disclosure. As shown in FIG. 12, the peripheral circuit may apply a read voltage Vrd to the target word lines respectively coupled to the plurality of memory blocks Block0˜BlockN simultaneously, apply a corresponding input voltage Vin to a plurality of target select lines respectively coupled to the plurality of memory blocks Block0˜BlockN simultaneously, and sense a current on a bit line coupled to the plurality of memory blocks Block0˜BlockN, where the current on the bit line is a sum of the results obtained after performing a multiplication operation on all memory strings coupled to the bit line. Therefore, the plurality of memory blocks can be operated in parallel, so that the operation efficiency and the computing power of the semiconductor device can be further improved.

It should be understood that all select lines in one memory block may be selected as the target select lines, or some select lines in the memory block may be selected as target select lines, and some select lines may be selected as non-target select lines. The non-target select lines and the select lines in the non-target memory block coupled to the same bit line are applied with an inhibit select voltage at the operation phase, so as to turn off the select gates coupled thereto.

In some examples, as shown in FIG. 10, the memory plane includes a plurality of memory blocks disposed in the second direction, the bit line layer includes a plurality of bit line groups disposed in parallel in the second direction, and the bit lines of each bit line group extend along the second direction to be coupled to all the memory strings of one memory string column in some of the memory blocks in the memory plane; the peripheral circuit includes a plurality of page buffers, and each page buffer is correspondingly connected to one bit line.

When data access is performed with a semiconductor device, the peripheral circuit is configured to: simultaneously perform a read operation on a plurality of memory blocks coupled to different bit line groups in a memory plane.

Data access includes a program operation to write data to memory cells and a read operation to read data. It may be understood that the memory blocks corresponding to each bit line group may independently perform a program operation and a read operation. Referring back to FIG. 8 and FIG. 10, each memory string in FIG. 8 is coupled to two bit lines, and each memory string in FIG. 10 is coupled to 1 bit line, that is, compared with the number of bit lines in the bit line group in FIG. 8, the number of bit lines in the bit line group in FIG. 10 is halved, and the data read from the bit line group at a time is halved. When performing the data read operation, in order for the semiconductor devices shown in FIG. 8 and FIG. 10 to read the same amount of data from the memory plane at a time, a read operation can be performed simultaneously on a plurality of memory blocks coupled to different bit line groups. For example, the memory plane is coupled to two bit line groups, and the read operation can be performed simultaneously on two memory blocks located in different bit line groups.

It should be noted that, in some examples, the program operation during data access may be performed in units of memory blocks, and data is written to all memory cells coupled to the same word line in a memory block at a time, so that on the premise that the numbers of memory strings included in the memory blocks shown in FIG. 8 and FIG. 10 are the same, data written into the memory plane by the two semiconductor devices at a time may be the same.

In some examples, the plurality of bit line groups includes a first bit line group coupled to a first target memory block and a second bit line group coupled to a second target memory block. The first bit line group and the second bit line group are any two of the plurality of bit line groups. The number of first target memory blocks may be one or more, and the number of second target memory blocks may be one or more.

The peripheral circuit is configured to: apply a plurality of first input voltages to a plurality of first target select lines coupled to a plurality of first target memory strings within the first target memory block, where the plurality of first input voltages are related to a plurality of first input values in the first input vector; sense a first current on a first bit line coupled to the first target memory string within the first bit line group; and apply a plurality of second input voltages to a plurality of second target select lines coupled to a plurality of second target memory strings within the second target memory block, where the plurality of second input voltages are related to a plurality of second input values in the second input vector; and sense a second current on a second bit line coupled to the second target memory string within the second bit line group.

As shown above, each bit line group and the memory block coupled to the bit line group may independently perform an operation of an input vector and a weight matrix. For example, the first bit line group and the first target memory block may independently perform an operation of the first input vector and the first weight matrix, and the second bit line group and the second target memory block may independently perform an operation of the second input vector and the second weight matrix. In some examples, an operation of the first input vector and the first weight matrix and an operation of the second input vector and the second weight matrix may also be performed simultaneously.

In some examples, the memory array includes a plurality of memory block layers, where each memory block layer includes at least one memory block; there are a plurality of bit line layers, and memory blocks of different memory block layers are coupled to bit lines in different bit line layers. The peripheral circuit is configured to simultaneously perform a read operation or an operation on a plurality of memory blocks located in different memory block layers and overlapping with each other along the third direction.

Based on the same reason as above, that is, the number of bit lines of the bit line group in FIG. 10 is halved compared to that in FIG. 8, then the data read from the bit line group at a time may be halved. When performing data access, in order for the semiconductor devices shown in FIG. 8 and FIG. 10 to read the same amount of data from the memory plane at a time, read operations may be simultaneously performed on a plurality of memory blocks located in different memory block layers and overlapping with each other along the third direction.

In addition, since each bit line group and the memory block coupled to the bit line group can independently perform an operation of one input vector and a weight matrix. Therefore, in some examples, the plurality of memory block layers includes a first memory block layer and a second memory block layer, where the first memory block layer includes a third target memory block coupled to the third bit line group; and the second memory block layer includes a fourth target memory block coupled to the fourth bit line group. The first memory layer and the second memory layer are any two memory layers in the plurality of memory layers. The number of the third target memory blocks may be one or more, and the number of the fourth target memory blocks may be one or more.

The peripheral circuit is configured to: correspondingly apply a plurality of third input voltages to a plurality of third target select lines coupled to a third target memory string within the third target memory block, where the plurality of third input voltages are related to a plurality of third input values in the third input vector, and sense a third current on a third bit line coupled to the third target memory string within the third bit line group; and correspondingly apply a plurality of fourth input voltages to a plurality of fourth target select lines coupled to a fourth target memory string within the fourth target memory block, where the plurality of fourth input voltages are related to a plurality of fourth input values in the fourth input vector, and sense a fourth current on a fourth bit line coupled to the fourth target memory string within the fourth bit line group.

That is, the memory blocks in each memory block layer may independently perform an operation of the input vector and the weight matrix. For example, the third target memory block of the first memory layer may independently perform an operation of the third input vector and the third weight matrix, and the fourth target memory block of the second memory layer may independently perform an operation of the fourth input vector and the fourth weight matrix. In some examples, an operation of the third input vector and the third weight matrix and an operation of the fourth input vector and the fourth weight matrix may also be performed simultaneously.

In some examples, the peripheral circuit may further obtain an operation result based on the output currents of the bit lines on the plurality of bit line groups.

In the examples of the present disclosure, when the number of the bit line groups coupled to the memory block increases and/or the plurality of memory layers are disposed, a more complex operation may be implemented to further improve the computing power of the semiconductor device. That is, it may be implemented without a large modification to the semiconductor device; in an example, it only needs to adjust the number of the bit line groups and adjust the algorithm without a large modification to the circuit, so that the operation performance of the semiconductor device can be improved without occupying more area of the chip.

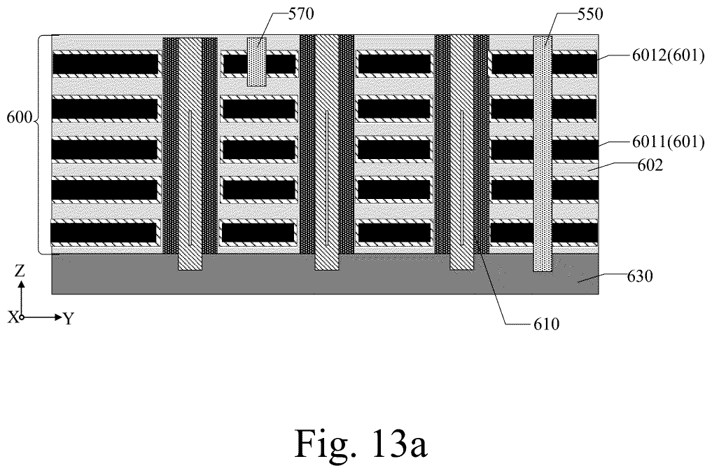

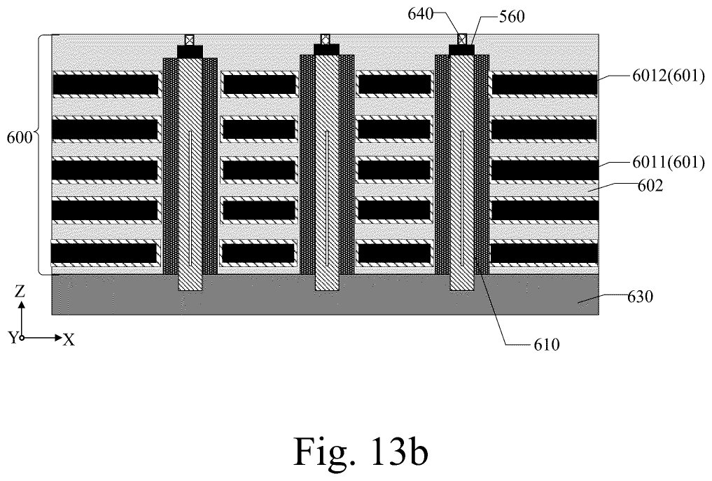

The examples of the present disclosure further provide a semiconductor device, FIG. 13a is a first schematic structural diagram of a semiconductor device according to an example of the present disclosure; and FIG. 13b is a second schematic structural diagram of a semiconductor device according to an example of the present disclosure. FIG. 13a and FIG. 13b show schematic structural diagrams of different cross-sections of the semiconductor device.

As shown in FIG. 6, FIG. 13a, and FIG. 13b, the semiconductor device includes a stack structure 600, a plurality of channel structures 610, at least one first isolation structure 550 extending along a first direction, and a bit line layer, the stack structure 600 includes gate layers 601 and dielectric layers 602 which are alternately stacked; the plurality of channel structures 610 are located in the stack structure 600 and penetrate through the stack structure 600; the first isolation structure 550 is located in the stack structure 600 and penetrates through the stack structure 600, the at least one first isolation structure 550 divides the stack structure 600 into a plurality of memory blocks in parallel along the second direction, each memory block includes a plurality of channel structure columns disposed in the first direction and a plurality of channel structure rows disposed in the second direction, each channel structure column includes a plurality of channel structures 610 disposed in the second direction, and each channel structure row includes a plurality of channel structures 610 disposed in the first direction. The first direction and the second direction are perpendicular to each other and are perpendicular to the stacking direction of the stack structure 600.

The bit line layer is located on a side of the stack structure 600 along the stacking direction, the bit line layer includes at least one bit line group, the bit line group includes a plurality of bit lines 560 disposed in the first direction, and each bit line 560 extends along the second direction and is coupled to all the channel structures 610 of one channel structure column in the memory block.

The following takes the stacking direction being the Z direction, the first direction being the X direction, and the second direction being the Y direction as an example to illustrate.

As shown in FIG. 13a and FIG. 13b, the gate layers 601 and the dielectric layers 602 are alternately stacked along the Z direction, and two adjacent gate layers 601 are separated by a dielectric layer 602. There are a plurality of gate layers 601 including a plurality of control gate layers 6011 and a select gate layer 6012 located on one side of the plurality of control gate layers 6011. The number of memory cells included in the memory string is mainly related to the number of control gate layers in the stack structure 600, and the number of select gates included in the memory string is related to the number of select gate layers.

The composition material of the gate layer 601 may include a conductive material. The conductive material includes, but is not limited to, tungsten (W), cobalt (Co), copper (Cu), aluminum (Al), polysilicon, doped silicon, silicide, metal nitride, or any combination thereof. Materials of the control gate layer and the select gate layer may be the same or different. In the semiconductor device shown in FIG. 13a, the control gate layer 6011 and the select gate layer 6012 may be formed in the same process step, and the materials of the control gate layer and the select gate layer are the same. In some implementations, each gate layer 601 includes a metal layer and a metal nitride layer surrounding the metal layer, e.g., a tungsten layer and a titanium nitride layer. In some implementations, each gate layer 601 includes a doped polysilicon layer. Each control gate layer may serve as a word line, and a select gate layer on one side of the control gate layer may serve as a select line. In some examples, the gate layer 601 may include a top select gate layer on one side of the plurality of control gate layers, and a bottom select gate layer on the other side of the plurality of control gate layers, where the top select gate layer serves as the top select line, and the bottom select gate layer serves as the bottom select line.

In some examples, the memory string 530 includes a channel structure 610 extending vertically through the stack structure 600. In some implementations, the channel structure 610 includes a semiconductor channel and a dielectric material (e.g., a memory film). In some implementations, the semiconductor channel includes silicon, e.g., polysilicon. In some implementations, the memory film is a composite dielectric layer including a tunneling layer, a storage layer (also referred to as a “charge trapping/storage layer”), and a blocking layer. The channel structure 610 may have a cylindrical shape (e.g., a pillar shape). According to some implementations, the semiconductor channel, the tunneling layer, the storage layer, and the blocking layer in this order are disposed radially from the center of the pillar toward the outer surface of the pillar. The tunneling layer may include silicon oxide, silicon oxynitride, or any combination thereof. The storage layer may include silicon nitride, silicon oxynitride, or any combination thereof. The blocking layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

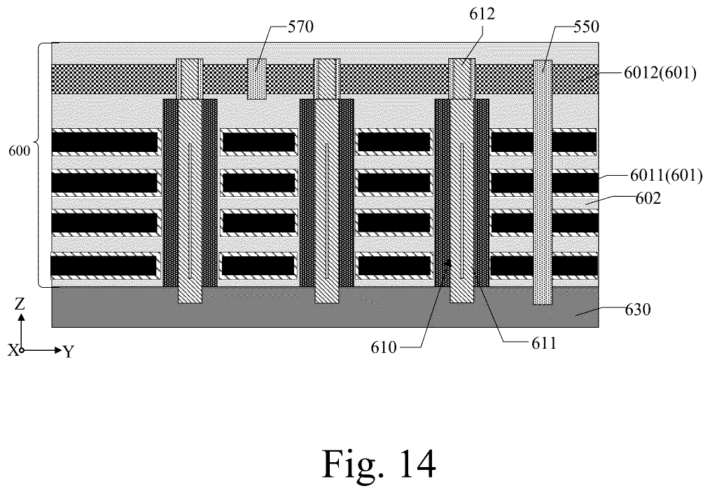

FIG. 14 is a third schematic structural diagram of a semiconductor device according to an example of the present disclosure. As shown in FIG. 14, in some examples, the control gate layer 6011 and the select gate layer 6012 may be formed in different process steps. For example, a control gate layer 6011 and a first sub-channel structure 611 located therein are formed first, then a select gate layer 6012 and a second sub-channel structure 612 located therein are formed, the first sub-channel structure 611 and the second sub-channel structure 612 jointly form a channel structure 610, and the channel layers of the first sub-channel structure 611 and the second sub-channel structure 612 are in contact with each other. In such a semiconductor device, the materials of the control gate layer 6011 and the select gate layer 6012 may be different, and the materials of the first sub-channel structure 611 and the second sub-channel structure 612 may be different. For example, the first sub-channel structure 611 includes a semiconductor channel and a memory film surrounding the semiconductor channel, and the second sub-channel structure 612 includes a semiconductor channel and an insulating layer surrounding the semiconductor channel.

In some examples, the stack structure 600 may be disposed on the semiconductor layer 630. The semiconductor layer 630 may include silicon (e.g., monocrystalline silicon), silicon germanium (SiGe), gallium arsenide (GaAs), germanium (Ge), silicon-on-insulator (SOI), germanium-on-insulator (GOI), or any other suitable material.

As shown in FIG. 6, FIG. 13a, and FIG. 14, the first isolation structure 550 is located in the stack structure 600 and penetrates through the stack structure 600, and the first isolation structure 550 extends along the first direction (X direction) to cut the stack structure 600 into a plurality of memory blocks. For example, the material of the first isolation structure 550 may include one or more of dielectric materials such as silicon oxide, silicon nitride, or silicon oxynitride.

In some examples, the semiconductor device further includes: at least one second isolation structure 570 extending along the first direction, located in the stack structure 600 and penetrating through the select gate layer 6012, the at least one second isolation structure 570 divides the memory block into a plurality of tiles, each tile includes at least one channel structure row, the at least one channel structure row includes one channel structure 610 in each of the plurality of channel structure columns. For example, the material of the second isolation structure 570 may include one or more of dielectric materials such as silicon oxide, silicon nitride, or silicon oxynitride.

In some examples, some of the segments of the bit line overlaps with the channel structure 610 in the stacking direction (Z direction). As shown in FIG. 6 and FIG. 13b, the bit line 560 may be located directly above the channel structure 610, and only one bit line 560 is disposed directly above each channel structure 610, which can increase the distance between adjacent bit lines, thereby reducing the coupling capacitance between the bit lines.

In some examples, a size of a width of the bit line 560 along the first direction (X direction) is: greater than or equal to 20 nm, and less than or equal to 100 nm. In the semiconductor device shown in FIGS. 5 and 8, the size of the width of the bit line is 10 nm-50 nm. In this example, since the spacing between adjacent bit lines increases, the size of the width of the bit line can be increased to 20 nm-100 nm on the premise of ensuring that the coupling capacitance is not increased, which can reduce the resistance of the bit line, further reducing the voltage drop on the bit line during the operation phase, and improving the calculation accuracy.

In some examples, as shown in FIG. 13b, the semiconductor device further includes a bit line plug 640 located on a side of the bit line facing away from the stack structure 600, and the bit line plug 640 is located at an end or middle of the bit line and is in contact with the bit line 560. The bit line plug 640 may serves as a current input/output terminal of the bit line, which couples the bit line to the peripheral circuit by being in contact with the interconnect line.

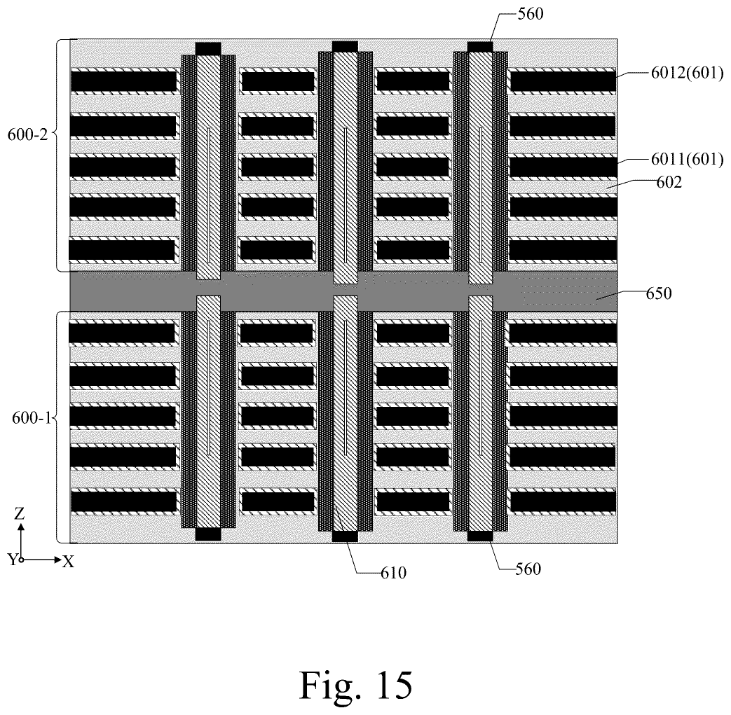

FIG. 15 is a fourth schematic structural diagram of a semiconductor device according to an example of the present disclosure. As shown in FIG. 15, there are a plurality of stack structures 600 stacked in a stacking direction (Z direction), and a plurality of channel structures 610 and a first isolation structure are disposed in each stack structure 600. There are a plurality of bit line layers, and the channel structures 610 within different stack structures 600 are coupled to bit lines 560 in different bit line layers.

In this example, each memory block layer includes one stack structure 600. The plurality of stack structures 600 are stacked along the Z direction to form a plurality of memory block layers.

In some examples, as shown in FIG. 15, the semiconductor device further includes a source line layer 650 located between the first stack structure 600-1 and the second stack structure 600-2, the source line layer 650 includes at least one source line, the channel structures 610 in the first stack structure 600-1 and the second stack structure 600-2 all extend into the source line layer 650, and the channel structures 610 in the two memory blocks overlapped along the stacking direction in the first stack structure 600-1 and the second stack structure 600-2 are coupled to the same source line; the bit line layer coupled to the first stack structure 600-1 is located on one side of the first stack structure 600-1 facing away from the second stack structure 600-2, and the bit line layer coupled to the second stack structure 600-2 is located on one side of the second stack structure 600-2 facing away from the first stack structure 600-1.

It should be noted that, in some examples, the source line layer 650 may be formed in a semiconductor layer, for example, a highly doped well region may be doped to form a source line in the semiconductor layer. In other examples, when the semiconductor device does not include a semiconductor layer, the source line may be formed by a deposition process or the like.

In some examples, the semiconductor device in the above example includes a three-dimensional NAND type memory.

In some examples, the semiconductor device in the above example includes a first semiconductor structure and a second semiconductor structure, the peripheral circuit is located in the first semiconductor structure, the memory array is located in the second semiconductor structure, and the first semiconductor structure and the second semiconductor structure are stacked along a thickness direction of the semiconductor device and coupled to each other. For example, the first semiconductor structure and the second semiconductor structure are bonded to each other to achieve an electrical connection.

In some examples, the semiconductor device includes a first semiconductor structure and a plurality of second semiconductor structures located on one side of the first semiconductor structure, the plurality of second semiconductor structures are stacked along a third direction and bonded to each other, the first semiconductor structure is bonded to the second semiconductor structure, each second semiconductor structure includes at least one memory block layer, and the first semiconductor structure includes a peripheral circuit.

For example, each second semiconductor structure includes at least one stack structure for forming a memory block layer.

In the examples of the present disclosure, the first semiconductor structure and the second semiconductor structure of the semiconductor device may be formed by bonding two wafers, for example, the first semiconductor structure may be formed on one wafer, the second semiconductor structure may be formed on the other wafer, and then the two wafers are bonded, the first semiconductor structure and the second semiconductor structure are stacked along a thickness direction of the semiconductor device, such a structure architecture can save the area of the semiconductor device and shorten the process cycle. When there are a plurality of second semiconductor structure, the plurality of second semiconductor structures may be formed on different wafers and bonded to each other.

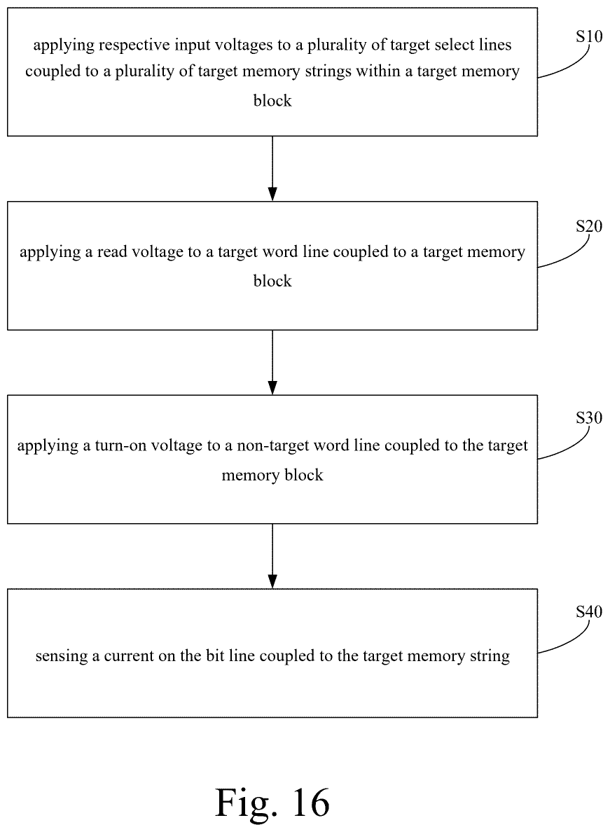

Based on a similar concept as the semiconductor device above, the present disclosure further provides an operating method of a semiconductor device, which may be performed by the semiconductor device according to any one of the above examples. FIG. 16 is a schematic flowchart of an operating method of a semiconductor device according to an example of the present disclosure, as shown in FIG. 16, when performing an in-memory operation by using the semiconductor device, the method may include operations S10, S20, S30, and S40.

At S10, the method may include applying respective input voltages to a plurality of target select lines coupled to a plurality of target memory strings within a target memory block; and

At S40, the method may include sensing a current on the bit line coupled to the target memory string.

In some examples, when performing an operation by using the semiconductor device, the operating method further includes:

At S20, the method may include applying a read voltage to a target word line coupled to a target memory block.

At S30, the method may include applying a turn-on voltage to a non-target word line coupled to the target memory block.

In some examples, when performing an operation by using the semiconductor device, the operating method further includes:
charging a sense node of a page buffer coupled to the bit line coupled to the target memory block to a first preset voltage, and applying a second preset voltage to a source line coupled to the target memory block.

In some examples, the plurality of memory cells in the target memory block have a first memory state and a second memory state, the threshold voltage of the memory cell having the first memory state is less than the threshold voltage of the memory cell having the second memory state; the read voltage is greater than the threshold voltage of the memory cell having the first memory state and is less than the threshold voltage of the memory cell having the second memory state.

In some examples, the current on the bit line coupled to the target memory block is the sum of the output currents of the plurality of memory strings coupled to the bit line in the target memory block; when the input voltage applied to the target select line coupled to the memory string causes the select gate coupled to the select line to be turned on, and the memory cell coupled to the target word line in the memory string has the first memory state, the output current of the memory cell is greater than or equal to a preset current.

In the examples of the present disclosure, the select line is one of a top select line and a bottom select line. The operating method further includes: applying a first select voltage to the other one of the top select line and the bottom select line.

In some examples, the memory array includes at least one memory plane, the memory plane includes a plurality of memory blocks disposed in the second direction, the bit line layer includes a plurality of bit line groups disposed in parallel in the second direction; the bit lines of each bit line group extend along the second direction to be coupled to all the memory strings of one memory string column in some of memory blocks in the memory plane, and the numbers of memory strings coupled to each bit line group are equal.

The plurality of bit line groups includes a first bit line group coupled to a first target memory block and a second bit line group coupled to a second target memory block.

Operation S10 may include applying a plurality of first input voltages to a plurality of first target select lines coupled to a plurality of first target memory strings within a first target memory block respectively, where the plurality of first input voltages are related to a plurality of first input values in a first input vector; and applying a plurality of second input voltages to a plurality of second target select lines coupled to a plurality of second target memory strings within the second target memory block respectively, where the plurality of second input voltages are related to a plurality of second input values in a second input vector.

Operation S40 may include sensing a first current on a first bit line coupled to a first target memory string within a first bit line group; and sensing a second current on a second bit line coupled to a second target memory string within a second bit line group.

In some examples, the plurality of memory blocks are arranged into a plurality of memory block layers along a third direction, where each memory block layer includes at least one memory block; there are a plurality of bit line layers, and the memory blocks of different memory block layers are coupled to bit lines of different bit line layers. The plurality of memory block layers includes a first memory block layer and a second memory block layer, the first memory block layer includes a third target memory block coupled to a third bit line group; and the second memory block layer includes a fourth target memory block coupled to a fourth bit line group.

Operation S10 may include applying a plurality of third input voltages to a plurality of third target select lines coupled to a third target memory string within a third target memory block respectively, where the plurality of third input voltages are related to a plurality of third input values in a third input vector; and applying a plurality of fourth input voltages to a plurality of fourth target select lines coupled to a fourth target memory string within a fourth target memory block respectively, where the plurality of fourth input voltages are related to a plurality of fourth input values in a fourth input vector.

Operation S40 may include sensing a third current on a third bit line coupled to the third target memory string within the third bit line group; and sensing a fourth current on a fourth bit line coupled to the fourth target memory string within the fourth bit line group.

In some examples, the operating method further includes: obtaining an operation result corresponding to the plurality of memory blocks coupled to the bit line group based on the current on the bit line in the bit line group; and performing a logical operation based on the operation result corresponding to the plurality of bit line groups.

In some examples, the operating method further includes: before performing the operation by using the semiconductor device, applying a corresponding program voltage to the target word line coupled to the target memory block to program the memory cell coupled to the target word line.

In an example of the present disclosure, the operating method of the semiconductor device includes: inputting a plurality of input voltages corresponding to an input vector to a memory block from a plurality of select lines coupled to a target memory block respectively, and applying a read voltage to a target word line coupled to the target memory block, and applying a turn-on voltage to a non-target word line coupled to the target memory block, which allows a multiplier used in a multiplication operation on a memory string coupled to different select lines to be different, thereby improving flexibility of operations performed by a semiconductor device including the three-dimensional NAND type memory. In addition, since the number of memory strings coupled to each bit line is increased, the number of bits of the input vector parallel input can be increased, thereby improving the computing power of the semiconductor device including the three-dimensional NAND type memory.

Based on a similar concept as the semiconductor device above, the present disclosure further provides a system, including: at least one semiconductor device according to any one of the above examples, and a controller coupled to the semiconductor device and configured to control the semiconductor device.

In some examples, the controller is configured to send a weight matrix and an input matrix to the semiconductor device and to receive an operation result of the semiconductor device. Here, the operation result of the semiconductor device is an operation result obtained after the analog-to-digital conversion.

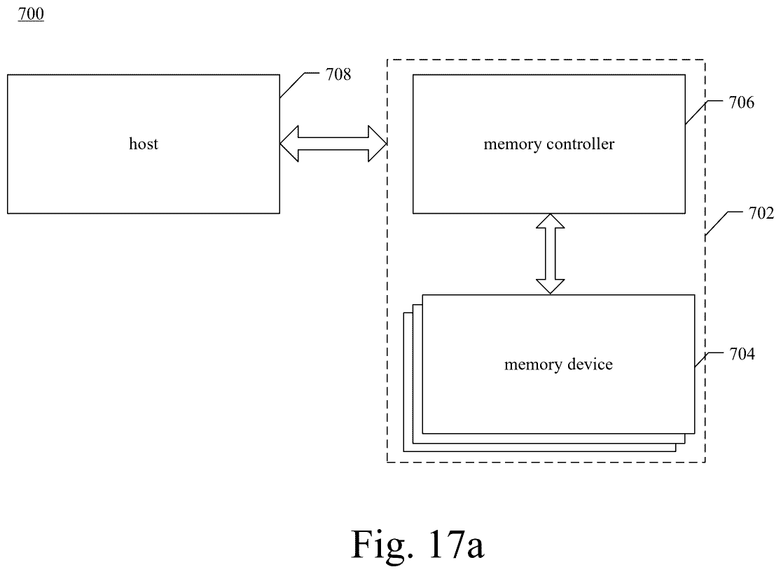

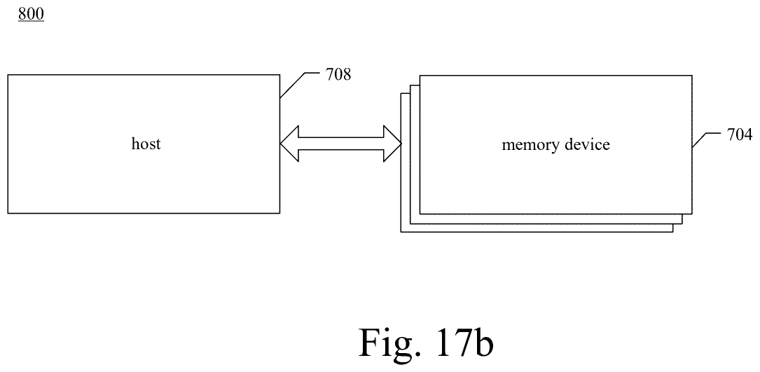

In some examples, the system in the above example may be the memory system 702 shown in FIG. 17a, the memory system 702 includes a memory controller 706 and a memory device 704 coupled to the memory controller 706, the controller in the above example may be the memory controller 706, and the semiconductor device may be the memory device 704. The memory controller 706 is coupled to the memory device 704 and the host 708 and is configured to control operations of the memory device 704, such as read, erase, program, compute operations. The memory controller 706 may manage data stored in the memory device 704 and communicate with the host 708.

In some other examples, the system in the above example may be the system 800 shown in FIG. 17b, the system 800 includes a host 708 and a memory device 704 coupled to the host 708, and the controller in the above examples may be a CPU in the host-side device. The semiconductor device in the above example may be the memory device 704.

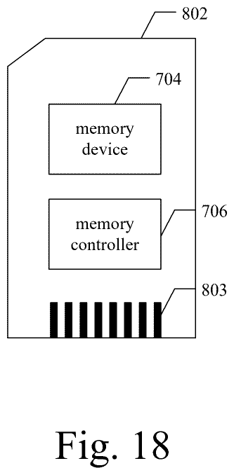

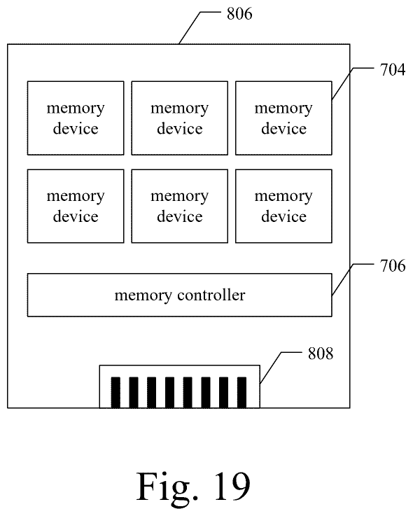

In one example as shown in FIG. 18, the system may be integrated into the memory card 802, the semiconductor device in the system may be the memory 704 in the memory card 802, and the controller in the system may be the memory controller 706 in the memory card 802. The memory card 802 may be one of a compact flash memory card, a Smart Media Card (SMC), a Memory Stick (MS), a Multi-Media Card (MMC), for example, an RS-MMC, an MMCmicro, an eMMC, or the like, a secure digital card, for example, a Mini SD card, a Micro SD card, an SDHC card, or the like, and a universal flash memory card. The memory card 802 may also include a memory card connector 804 that couples the memory card 802 to the host. In another example as shown in FIG. 19, the system may be integrated into a Solid State Disk (SSD) 806, the semiconductor device in the system may be the memory device 704 in the solid state disk 806, and the controller in the system may be the memory controller 706 in the solid state disk 806. The solid state disk 806 may further include a solid state disk connector 808 that couples the solid state disk 806 to the host-side device. In some implementations, the storage capacity and/or operating speed of the solid state disk 806 is greater than the storage capacity and/or the operating speed of the memory card 802.

In some other examples, the system may be integrated in the terminal device, the controller may be a Central Processing Unit (CPU) of the terminal device, and the terminal device may include, but is not limited to, a mobile phone, a smart television, a smart speaker, a wearable device, a tablet computer, a desktop computer, a computer integrated machine, a handheld computer, a notebook computer, a server, an Ultra-Mobile Personal Computer (UMPC), a netbook, a Personal Digital Assistant (PDA), a laptop, a mobile computer, an Augmented Reality (AR) device, a Virtual Reality (VR) device, an Artificial Intelligence (AI) device, or any terminal device or a portable terminal device.

It should be understood that the system includes, but is not limited to, a memory system. For example, the system may include a memory system and a computing in memory system, for example, a computing in memory system including a memory system and a processor, where the processor includes at least one of a CPU, a GPU, or an NPU. In an implementation, the system may be a computing in memory SoC (system on chip).

The features disclosed in the several device examples according to the present disclosure may be arbitrarily combined without conflict, to obtain a new device example.

The methods disclosed in the several method examples according to the present disclosure may be arbitrarily combined without conflict, to obtain a new method example.

The above descriptions are only specific aspects of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A semiconductor device, comprising:
a memory array comprising at least one memory block, wherein the memory block comprises a plurality of memory string columns disposed in a first direction, each of the memory string columns comprises a plurality of memory strings disposed in a second direction perpendicular to the first direction, and each of the memory strings comprises a plurality of memory cells disposed along a third direction and connected in series; and
a bit line layer comprising at least one bit line group, wherein the bit line group comprises a plurality of bit lines disposed in the first direction, and each of the bit lines extends along the second direction and is coupled to all memory strings of one of the memory string columns within the memory block.

2. The semiconductor device of claim 1, wherein:
the plurality of memory strings in the memory block are arranged into a plurality of memory string rows in the second direction, and
the memory block is divided into a plurality of tiles in the second direction, wherein each of the tiles comprises at least one of the memory string rows, the at least one of the memory string rows comprises one of the memory strings in each of the plurality of memory string columns, and the memory strings of each of tiles are coupled to a same select line.

3. The semiconductor device of claim 2, wherein the memory strings in adjacent memory string columns are staggered disposed.

4. The semiconductor device of claim 2, wherein:
the memory array comprises at least one memory plane, and the memory plane comprises a plurality of memory blocks disposed in the second direction, and
the bit lines of the bit line group extend along the second direction to be coupled to all memory strings of one of the memory string columns within each of the memory blocks in the memory plane.

5. The semiconductor device of claim 2, wherein:
the memory array comprises at least one memory plane, and the memory plane comprises a plurality of memory blocks disposed in the second direction, and
the bit line layer comprises a plurality of bit line groups disposed in parallel in the second direction, the bit lines of each of the bit line groups extend along the second direction to be coupled to all memory strings of one memory string column within some of the memory blocks in the memory plane, and a number of the memory blocks coupled to each of the bit line groups are equal.

6. The semiconductor device of claim 4, wherein:
a current input/output terminal of the bit line is disposed at an end of the bit line, or the current input/output terminal of the bit line is disposed in the middle of the bit line.

7. The semiconductor device of claim 2, further comprising:
a peripheral circuit coupled to the bit line and the select line,
wherein when performing an operation by using the semiconductor device, a plurality of target memory strings in a target memory block in the memory array are configured to store a plurality of weight values, and
wherein the peripheral circuit is configured to:
apply respective input voltages to a plurality of target select lines coupled to the plurality of target memory strings within the target memory block; and
sense currents on the bit lines coupled to the target memory strings.

8. The semiconductor device of claim 5, further comprising:
a peripheral circuit coupled to the bit line and the select line,
wherein when the semiconductor device performs data access, the peripheral circuit is configured to:
perform a read operation simultaneously on the plurality of memory blocks coupled to different bit line groups within the memory plane.

9. The semiconductor device of claim 2, wherein:
the memory block comprises a plurality of memory blocks arranged into a plurality of memory block layers along the third direction, and each of the memory block layers comprises at least one memory block, and
the bit line layer comprises a plurality of bit line layers, and memory blocks of different memory block layers are coupled to bit lines in different bit line layers.

10. The semiconductor device of claim 9, further comprising:
a peripheral circuit coupled to the bit line and the select line,
wherein the peripheral circuit is configured to perform a read operation or an operation simultaneously on the plurality memory blocks that are located in the different memory block layers and overlap with each other along the third direction.

11. The semiconductor device of claim 9, further comprising:
a source line layer located between a first memory block layer and a second memory block layer,
wherein the source line layer comprises at least one source line, memory strings in two of the memory blocks overlapping along the third direction in the first memory block layer and the second memory block layer are coupled to a same source line, and
wherein a bit line layer coupled to a memory block of the first memory block layer is located on a side of the first memory block layer facing away from the second memory block layer, and a bit line layer coupled to a memory block of the second memory block layer is located on a side of the second memory block layer facing away from the first memory block layer.

12. The semiconductor device of claim 1, further comprising:
a peripheral circuit comprising:
an analog-to-digital conversion circuit;
a digital-to-analog conversion circuit;
a voltage generator;
a column decoder; and
a control logic,
wherein the analog-to-digital conversion circuit is coupled to the column decoder and the control logic, and the digital-to-analog conversion circuit is coupled to the voltage generator and the control logic.

13. A semiconductor device, comprising:
a stack structure comprising gate layers and dielectric layers alternately stacked;
a plurality of channel structures located in the stack structure and penetrating through the stack structure;
at least one first isolation structure extending along a first direction, located in the stack structure and penetrating through the stack structure, wherein the at least one first isolation structure divides the stack structure into a plurality of memory blocks in parallel along a second direction, each of the memory blocks comprises a plurality of channel structure columns disposed in the first direction, each of the channel structure columns comprises a plurality of channel structures disposed in the second direction, and the first direction and the second direction are perpendicular to each other and both perpendicular to a stacking direction of the stack structure; and
a bit line layer located on a side of the stack structure along the stacking direction, wherein the bit line layer comprises at least one bit line group, the bit line group comprises a plurality of bit lines disposed in the first direction, and each of the bit lines extends along the second direction and coupled to all the channel structures of one of the channel structure columns within the memory block.

14. The semiconductor device of claim 13, wherein a segment of the bit line overlap with the channel structures in the stacking direction.

15. The semiconductor device of claim 13, wherein a size of a width of the bit line along the first direction is greater than or equal to 20 nm and less than or equal to 100 nm.

16. The semiconductor device of claim 13, wherein:
the gate layer comprises a plurality of gate layers,
the plurality of gate layers comprise a plurality of control gate layers and a select gate layer located on a side of the plurality of control gate layers,
all the channel structures in the memory block are arranged into a plurality of channel structure rows in the second direction, and
the semiconductor device further comprises:
at least one second isolation structure extending along the first direction, located in the stack structure and penetrating through the select gate layer, wherein the at least one second isolation structure divides the memory block into a plurality of tiles, each of the tiles comprises at least one of the channel structure rows, and the at least one of the channel structure rows comprises one of the channel structures in each of the plurality of channel structure columns.

17. The semiconductor device of claim 13, further comprising:
a bit line plug located on a side of the bit line facing away from the stack structure,
wherein the bit line plug is located at an end or a middle of the bit line and is in contact with the bit line.

18. The semiconductor device of claim 13, wherein:
the stack structure comprises a plurality of stack structures stacked along the stacking direction,
the plurality of channel structures and the first isolation structure are disposed within each of the stack structures,
the bit line layer comprises a plurality of bit line layers, and
the channel structures in different ones of the stack structures are coupled to bit lines in different ones of the bit line layers.

19. The semiconductor device of claim 18, further comprising:
a source line layer located between a first stack structure and a second stack structure,
wherein the source line layer comprises at least one source line, channel structures in the first stack structure and the second stack structure both extend into the source line layer, and channel structures in two of the memory blocks that overlap along the stacking direction in the first stack structure and the second stack structure are coupled to a same source line, and
wherein a bit line layer coupled to the first stack structure is located on a side of the first stack structure facing away from the second stack structure, and a bit line layer coupled to the second stack structure is located on a side of the second stack structure facing away from the first stack structure.

20. A method of operating a semiconductor device, comprising:
when performing an in-memory operation by using the semiconductor device,
applying respective input voltages to a plurality of target select lines coupled to a plurality of target memory strings in a target memory block; and
sensing currents on bit lines coupled to the target memory strings, wherein the semiconductor device comprises:
at least one memory block comprising a plurality of memory string columns disposed in a first direction and a plurality of memory string rows disposed in a second direction perpendicular to the first direction, wherein the memory block is divided into a plurality of tiles in the second direction, each of the tiles comprises at least one of the memory string rows, the at least one of the memory string rows comprises one memory string in each of the plurality of memory string columns, all memory strings of each of the tiles are coupled to a same select line;
a bit line layer comprising at least one bit line group, wherein the bit line group comprises a plurality of bit lines, each of the bit lines is coupled to all memory strings in one memory string column within the memory block; and
a peripheral circuit coupled to the select line and the bit line.
